(19) United States
(12) Patent Application Publication
(10) Pub. No.: US 2025/0393211 A1
(43) Pub. Date: Dec. 25, 2025

(54) MANUFACTURING METHOD FOR SEMICONDUCTOR DEVICE

(71) Applicant: Kioxia Corporation, Tokyo (JP)

(72) Inventors: Yurika KANNO, Yokkaichi Mie (JP); Tatsuhiko KOIDE, Kuwana Mie (JP)

(73) Assignee: Kioxia Corporation, Tokyp (JP)

(21) Appl. No.: 18/981,454

(22) Filed: Dec. 14, 2024

(30) Foreign Application Priority Data
Jun. 25, 2024 (JP) 2024-102346

(51) Int. Cl. H10B 43/27; G11C 16/04

(52) U.S. Cl. CPC H10B 43/27; G11C 16/0483

(57) ABSTRACT

A method for manufacturing a semiconductor device according to an embodiment includes: modifying a surface of a semiconductor layer using a compound having an alkoxysilyl group or a silanol group at one end and a cation-capturing organic group at the other end; treating the surface of the modified semiconductor layer with a metal ion-containing solution; washing the surface of the treated semiconductor layer; drying the surface of the washed semiconductor layer; and heating the surface of dried semiconductor layer in a non-oxidizing atmosphere.

### CROSS-REFERENCE TO RELATED APPLICATION

This application is based upon and claims the benefit of priority from Japanese Patent Application No. 2024-102346, filed on Jun. 25, 2024, the entire contents of which are incorporated herein by reference.

### FIELD

Embodiments described herein relate generally to a manufacturing method for a semiconductor device.

### BACKGROUND

A characteristic of a channel (semiconductor layer) of a semiconductor memory significantly affects performance of memory cell. As a technique for enhancing channel mobility, induced lateral crystallization (MILC) may be employed.

### BRIEF DESCRIPTION OF THE DRAWINGS

FIG. 1 is a schematic cross-sectional diagram of a semiconductor device according to an embodiment;

FIG. 2 is a flowchart for a manufacturing method for a semiconductor device according to an embodiment;

FIG. 3 is a schematic diagram for a manufacturing method for a semiconductor device according to an embodiment;

FIG. 4 is a schematic diagram for a manufacturing method for a semiconductor device according to an embodiment;

FIG. 5 is a schematic diagram for a manufacturing method for a semiconductor device according to an embodiment;

FIG. 6 is a schematic diagram for a manufacturing method for a semiconductor device according to an embodiment;

FIG. 7 is a schematic diagram for a manufacturing method for a semiconductor device according to an embodiment;

FIG. 8 is a schematic diagram for a manufacturing method for a semiconductor device according to an embodiment;

FIG. 9 is a schematic diagram for a manufacturing method for a semiconductor device according to an embodiment;

FIG. 10 is a schematic diagram for a manufacturing method for a semiconductor device according to an embodiment;

FIG. 11 is a schematic diagram for a manufacturing method for a semiconductor device according to an embodiment;

FIG. 12 is a schematic diagram for a manufacturing method for a semiconductor device according to an embodiment;

FIG. 13 is a schematic diagram for a manufacturing method for a semiconductor device according to an embodiment;

FIG. 14 is a schematic diagram for a manufacturing method for a semiconductor device according to an embodiment;

FIG. 15 is a schematic diagram for a manufacturing method for a semiconductor device according to an embodiment;

FIG. 16 is a schematic diagram for a manufacturing method for a semiconductor device according to an embodiment;

FIG. 17 is a schematic diagram for a manufacturing method for a semiconductor device according to an embodiment;

FIG. 18 is a schematic diagram for a manufacturing method for a semiconductor device according to an embodiment;

FIG. 19 is a schematic diagram for a manufacturing method for a semiconductor device according to an embodiment;

FIG. 20 is a schematic diagram for a manufacturing method for a semiconductor device according to an embodiment;

FIG. 21 is a schematic perspective diagram of a semiconductor device according to an embodiment;

FIG. 22 is a schematic cross-sectional diagram of a semiconductor device according to an embodiment;

FIG. 23 is a schematic cross-sectional diagram of a semiconductor device according to an embodiment;

FIG. 24 is a flowchart for a manufacturing method for a semiconductor device according to an embodiment;

FIG. 25 is a schematic diagram for a manufacturing method for a semiconductor device according to an embodiment;

FIG. 26 is a schematic diagram for a manufacturing method for a semiconductor device according to an embodiment;

FIG. 27 is a schematic diagram for a manufacturing method for a semiconductor device according to an embodiment;

FIG. 28 is a schematic diagram for a manufacturing method for a semiconductor device according to an embodiment;

FIG. 29 is a schematic diagram for a manufacturing method for a semiconductor device according to an embodiment;

FIG. 30 is a schematic diagram for a manufacturing method for a semiconductor device according to an embodiment;

FIG. 31 is a schematic diagram for a manufacturing method for a semiconductor device according to an embodiment;

FIG. 32 is a schematic diagram for a manufacturing method for a semiconductor device according to an embodiment;

FIG. 33 is a schematic diagram for a manufacturing method for a semiconductor device according to an embodiment;

FIG. 34 is a schematic diagram for a manufacturing method for a semiconductor device according to an embodiment;

FIG. 35 is a schematic diagram for a manufacturing method for a semiconductor device according to an embodiment;

FIG. 36 is a schematic diagram for a manufacturing method for a semiconductor device according to an embodiment.

### DETAILED DESCRIPTION

A method for manufacturing a semiconductor device according to an embodiment includes: modifying a surface of a semiconductor layer using a compound having an alkoxysilyl group or a silanol group at one end and a cation-capturing organic group at the other end; treating the surface of the modified semiconductor layer with a metal ion-containing solution; washing the surface of the treated semiconductor layer; drying the surface of the washed semiconductor layer; and heating the surface of dried semiconductor layer in a non-oxidizing atmosphere.

Hereinafter, embodiments will be described with reference to the drawings.

In this specification, several elements are given a plurality of expression examples. These expression examples are merely examples, and do not deny that the above-described elements are expressed by other expressions. An element to which a plurality of expressions is not given may also be expressed by another expression.

The drawings are schematic, and a relationship between a thickness and a plane dimension, a ratio between thicknesses of layers, and the like may be different from actual relationship and ratios. In addition, the drawings may include portions having different dimensional relationships and ratios. In the drawings, some reference numerals are omitted.

In the specification, physical characteristic values described in the embodiments are values at atmospheric pressure and 25° C. In addition, values of diameters are values of circumscribed circle diameters.

In the specification, hyphen (-) and equal (=) in the embodiments represent bond for expressions of chemical formulas.

In this specification, steps include not only independent steps but also other steps and combinations with other treatments. In numerical conditions in this specification, when a plurality of numerical ranges is described, an upper limit value or a lower limit value of the numerical range may be substituted with an upper limit value or a lower limit value of another numerical range. When the upper limit value and the lower limit value of the numerical condition in this specification are described, the numerical condition may be remounted with a condition of a numerical range in which the upper limit value and the lower limit value are combined.

### First Embodiment

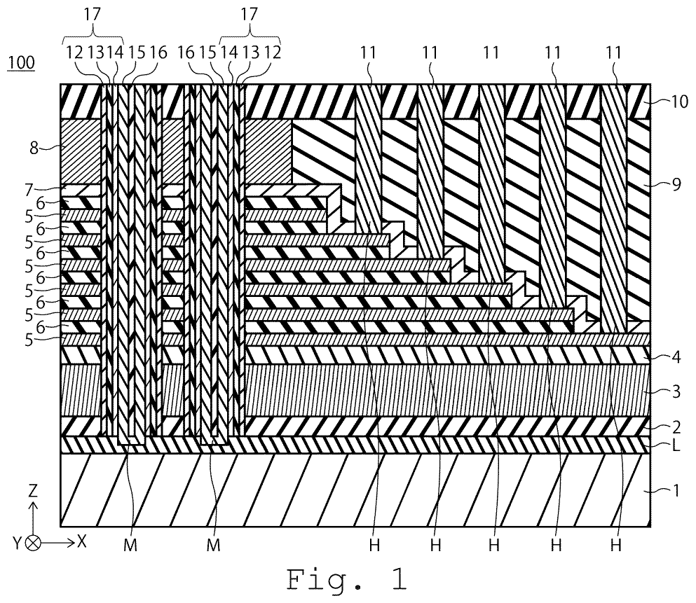

The first embodiment relates to a manufacturing method for a semiconductor device. As a semiconductor device, FIG. 1 shows a schematic cross-sectional diagram of a semiconductor device 100 of the first embodiment. The semiconductor device 100 of FIG. 1 has a structure of a three-dimensional semiconductor memory. The semiconductor device 100 shown in FIG. 1 is an example of the three-dimensional semiconductor memory and illustrates a portion of the three-dimensional semiconductor memory. A manufacturing method of the first embodiment is preferably applied to openings, such as memory-holes. In this embodiment, the manufacturing method for the semiconductor device will be described following the description of the semiconductor device 100. The semiconductor device 100 of the first embodiment includes bundled NAND-strings, each consisting of vertically stacked, series-connected vertical transistors.

The semiconductor device 100 of FIG. 1 comprises a substrate 1, a lower insulating film 2, a source-side conductive layer 3, an upper insulating film 4, a plurality of electrode layer 5, a plurality of insulating layer 6, a cover insulating film 7, a drain-side conductive layer 8, a first interlayer insulating film 9, a second interlayer insulating film 10, multiple contact plugs 11, a block insulating film 12 as an example of a second insulating film, a charge trap layer 13, a tunnel insulating film 14 as an example of a first insulating film, a channel semiconductor layer 15, and a core insulator 16 as an example of a third insulating film.

The substrate 1 is a semiconductor substrate, for example, Si (silicon) substrate. FIG. 1 illustrates X direction and Y direction which are orthogonal to a surface of the substrate 1 and perpendicular each other and Z direction which is perpendicular to the surface of the substrate 1. In the specification, +Z (plus Z) direction means upper direction and −Z (minus Z) direction means lower direction. The −Z direction may or may not correspond to the gravity direction. The Z direction corresponds as an example of a first direction.

A diffusion layer L is located in the substrate 1 on a side of the lower insulating film 2. The diffusion layer L includes, for example, a p-well and an n-well.

The lower insulating film 2 is located on the diffusion layer L which is formed in the substrate 1. The lower insulating film 2 is an insulator expanding in the X-Y plane (horizontally). The lower insulating film 2 includes, for example, silicon oxide.

The source-side conductive layer 3 is formed on the lower insulating film 2. The source-side conductive layer 3 is electrically conductive and expands in the X-Y plane. The source-side conductive layer 3 includes, for example, silicon doped with phosphorus (P).

The upper insulating film 4 is formed on the source-side conductive layer 3. The upper insulating film 4 is an insulator expanding in the X-Y plane. The upper insulating film 4 includes, for example, silicon oxide.

The plurality of electrode layer (electrode layers) 5 and the plurality of the insulating layers 6 are stacked alternately on the upper insulating film 4 in the Z direction. The electrode layers 5 are electrically conductive layers, for example, metal layers. The electrode layers 5 expand in the X-Y plane. The electrode layers 5 can function as word line and selector line. The electrode layers 5 include, for example, tungsten (W). The number of the electrode layers 5 is, for example, 64 or more.

The plurality of the insulating layer (insulating layers) 6 and the electrode layers 5 are stacked alternately on the upper insulating film 4 in the Z direction. The insulating layers 6 are electrically insulative layers and expand in the X-Y plane. The insulating layers 6 include, for example, silicon oxide. The number of the insulating layers 6 is, for example, 64 or more.

FIG. 1 shows memory holes M and contact holes H. The memory holes M penetrate the electrode layers 5 and the insulating layers 6. The contact holes H which formed on a stair region of the electrode layers 5 and the insulating layers 6.

The cover insulating film 7 is an insulator that expands primarily in the X-Y plane. The cover insulating film 7 is located on the stacked member including the electrode layers 5 and the insulating layers 6. The cover insulating film 7 conforms to a stair-like shape corresponding to the stacked cross-section of the stair region and provided aligning with the stacked cross-section of the stair region on the side of the contact plug 11. The cover insulating film 7 include, for example, silicon oxide.

The drain-side conductive layer 8 is electrically conductive and expands primarily in the X-Y plane. The drain-side conductive layer 8 is formed on the cover insulating film 7 The drain-side conductive layer 8 includes, for example, polysilicon.

The first interlayer insulating film 9 is an insulator. The first interlayer insulating film 9 is located between the cover insulating film 7 and the second interlayer insulating film 10 in the Z direction. The first interlayer insulating film 9 is formed on the cover insulating film 7 so that the first interlayer insulating film 9 fill regions over the stair region (for example gaps between the contact plugs 11). The first interlayer insulating film 9 includes, for example, silicon nitride.

The second interlayer insulating film 10 is an insulator expanding in the X-Y plane. The second interlayer insulating film 10 is formed on both the drain-side conductive layer 8 and the first interlayer insulating film 9. The second interlayer insulating film 10 is, for example, a silicon nitride film.

The plurality of the contact plug (contact plugs) 11 is formed in the contact holes H, each of the contact holes penetrates the cover insulating film 7, the first interlayer insulating film 9, and the second interlayer insulating film 10. Each of the contact plugs 11 is electrically connected to the respective electrode layers 5. Each of the contact plugs 11 is made of a barrier metal, for example, Ti (titanium) containing layer and a plug member layer, for example a W (tungsten) layer.

The block insulating film 12 is located cylindrically in the memory holes M. The outer surface of the block insulating film 12 covers the sidewalls of the electrode layers 5 and the insulating layers 6 which are stacked alternately. The charge trap layer 13 is located inside of the block insulating film 12. The block insulating film 12 is, for example, SiO₂ film.

The charge trap layer 13 is located cylindrically in the memory holes M. The charge trap layer 13 is, for example, a silicon nitride film or a semiconductor film such a polysilicon layer or polysilicon germanium layer.

The tunnel insulating film 14 is located cylindrically in the memory holes M. The tunnel insulating film 14 is located between the charge trap layer 13 and the channel semiconductor layer 15 The tunnel insulating film 14 is, for example, a silicon oxide film. A thickness of the tunnel insulating film 14 is, for example, 5 [nm] or more and 10 [nm] or less.

The channel semiconductor layer 15 is located cylindrically in the memory holes M. The channel semiconductor layer 15 covers, for example, the surface of the core insulator 16. The channel semiconductor layer 15 is, for example, such a polysilicon layer or polysilicon germanium layer and electrically connected to the substrate 1 The under edge of the channel semiconductor layer 15 is located on the surface of the substrate 1 and connects Si (silicon) formed epitaxially and the other on the diffusion layer L. A thickness of the channel semiconductor layer 15 is, for example, 5 [nm] or more and 30 [nm] or less.

The channel semiconductor layer 15 may include a compound (silicide) containing Si and one or more elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W. The channel semiconductor layer 15 includes one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W and concentration of the metal element is 4×10¹⁷ [atoms/cm³] or less.

The core insulator 16 is located cylindrically in the memory holes M. The core insulator 16 includes, for example, silicon oxide.

A memory film 17 includes, stacked layers including the block insulating film 12, the charge trap layer 13, and the tunnel insulating film 14. The core insulator 16 is cylindrical in shape, extending mainly along in the Z-direction. The block insulating film 12, the charge trap layer 13,

the tunnel insulating film 14, the channel semiconductor layer 15, the core insulator 16 are arranged in this order in the memory holes which penetrate the lower insulating film 2, the source-side conductive layer 3, the upper insulating film 4, the electrode layers 5, the insulating layers 6, the cover insulating film 7, the drain-side conductive layer 8, and the second interlayer insulating film 10 The channel semiconductor layer 15, the tunnel insulating film 14, the charge trap layer 13, and the block insulating film 12 are cylindrical in shape, extending mainly along in the Z-direction and are around the core insulator 16 in this order.

The block insulating film 12, the charge trap layer 13, the tunnel insulating film 14, the channel semiconductor layer 15, and the core insulator 16 are formed, for example, following order. First, the block insulating film 12, the charge trap layer 13, and the tunnel insulating film 14 are formed on both the sidewalls of the memory holes M and the bottoms of the memory holes M. Next, portion of the layers of the tunnel insulating film 14, the charge trap layer 13, and the block insulating film 12 which are formed on the bottoms the memory holes M are selectively removed. After that, the channel semiconductor layer 15 and the core insulator 16 are filled in the memory holes M.

In this embodiment, the metal element(s) is inserted into the channel semiconductor layer 15 (semiconductor layer 21, semiconductor layer 21A described in later) before it undergoes crystallization. Subsequently, the channel semiconductor layer 15 semiconductor layer (semiconductor layer 21, 21A) with the inserted metal element(s) is crystalized. By virtue of these steps, the channel semiconductor layer 15 (semiconductor layer 21, semiconductor layer 21A) may be crystalized at low temperatures and diameter of crystal grains in the channel semiconductor layer 15 (semiconductor layer 21, semiconductor layer 21A) may be longer. As the result, the mobility of the channel semiconductor layer 15 may be increased and a threshold voltage of memory cells in the 3D semiconductor memory may be decreased. Before the crystallization of the channel semiconductor layer 15, the metal element(s) is migrated in the channel semiconductor layer 15 (semiconductor layer 21, semiconductor layer 21A) and promote grain growth.

When the channel semiconductor layer 15 (semiconductor layer 21, semiconductor layer 21A) with the inserted metal element(s) before the crystallization is crystallized, this embodiment enables that the diameter (outer circumstance diameter) of the crystal grains in the channel semiconductor layer 15 may become, for example, 80 [nm] or more and 1600 [nm] or less.

In this embodiment, after crystallization of the channel semiconductor layer 15 (semiconductor layer 21, semiconductor part of the metal element(s) in the channel layer 21A), semiconductor layer 15 is removed. This process allows the concentration of the metal element(s) in the channel semiconductor layer 15 may be reduced to 4×10¹⁷ [atoms/cm³] or less.

When the removing the metal element(s) in the channel semiconductor layer 15, a leak current through the tunnel insulating film 14 may be reduced comparing to cases where the metal element(s) is not removed.

The metal element(s) of this embodiment is, for example, Ni, but other metal element(s) may be also applicable. The metal element(s) of this embodiment are, for example, one or more selected from the group (first group) Au (gold), Cu (copper), Ag (silver), Pd (palladium), Ni (nickel), and Pt (platinum). The metal element(s) can also include one or more selected from the group (second group) consisting of Mn (manganese), Rh (rhodium), Co (cobalt), Fe (ferrite), Cr (chromium), Ti (titanium), Nb (niobium), Ir (iridium), Ta (tantalum), Re (rhenium), Mo (molybdenum), V (vanadium), Hf (hafnium), Ru (ruthenium), Zr (zirconium), and W (tungsten). Both the metal element(s) of the first group and the metal element(s) of the second group function lowering the temperature of crystallization of the channel semiconductor layer 15. The effect of the element(s) of the first group is generally greater than that of the element(s) of the second group.

When Al or/and Ti is used, it is preferable that an insulating film may be formed on the surface of the channel semiconductor layer 15 (semiconductor layer 21, semiconductor layer 21A) by performing oxidization or nitridation after the crystallization. When Al or/and Ti exist in the channel semiconductor layer 15, there is a possibility that short channel effect of the tunnel insulating film 14 and the channel semiconductor layer 15 is decreased. When the channel semiconductor layer 15 including Al is oxidized or nitridated, the insulating film, for example, AlOₓ film or AlN film is formed. Then, the degradation of the short channel effect may be reduced. Similarly, when the channel semiconductor layer 15 including Ti is oxidized, the insulating film, for example, TiOₓ film is formed. Then, the degradation of the short channel effect may be reduced.

The channel semiconductor layer 15 which already includes the metal element(s) may include one or more selected from the group consisting of B (boron), P (phosphorous), and As (arsenic). The channel semiconductor layer 15 of the embodiment may include one or more selected from the group consisting of B, P, and As. Concentration of one or more selected from the group consisting of B, P, and As is, for example, 1.0×10¹⁶ [atoms/cm³] or more and 1.0×10¹⁹ [atoms/cm³] or less. It enables that the threshold voltage of the memory cells in the 3D semiconductor memory is adjusted appropriately.

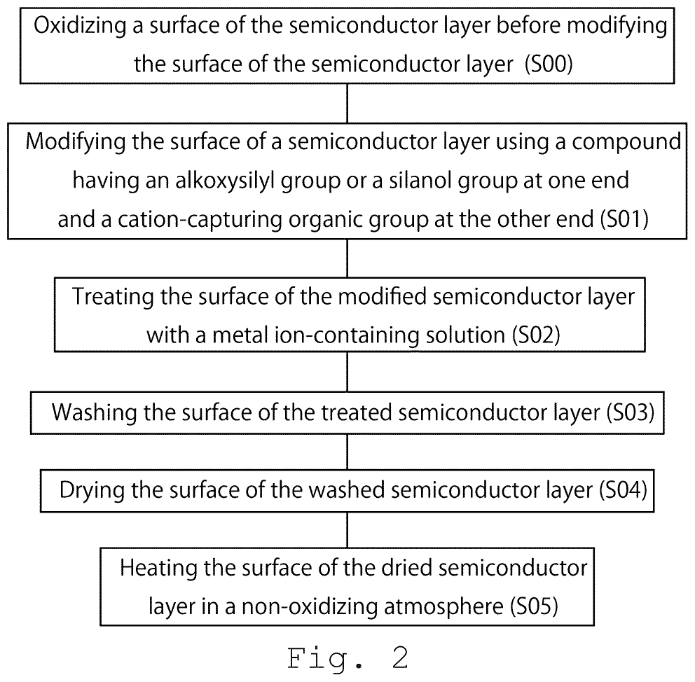

Next, a manufacturing method for the semiconductor device 100 will be described. A flowchart for the manufacturing method for the semiconductor device 100 is shown in FIG. 2. Schematic diagrams for the manufacturing method for the semiconductor device 100 are shown in FIG. 3 through FIG. 12. The manufacturing method described below represents a portion of the overall manufacturing method for the semiconductor device 100.

The manufacturing method for the semiconductor device includes oxidizing a surface of the semiconductor layer before modifying the surface of the semiconductor layer (S00), modifying the surface of the semiconductor layer using a compound having an alkoxysilyl group or a silanol group at one end and a cation-capturing organic group at the other end (S01), treating the surface of the modified semiconductor layer with a metal ion-containing solution (S02), washing the surface of the treated semiconductor layer with the metal ion-containing solution (S03), drying the surface of the washed semiconductor layer (S04), and heating the surface of the dried semiconductor layer in a non-oxidizing atmosphere (S05).

First, the lower insulating film 2, the source-side conductive layer 3, and the upper insulating film 4 are formed on the substrate 1 in this order (referring to FIG. 1). Subsequently, the electrode layers 5 and the insulating layers 6 are formed alternately on the upper insulating film 4 to obtain the member shown in FIG. 3.

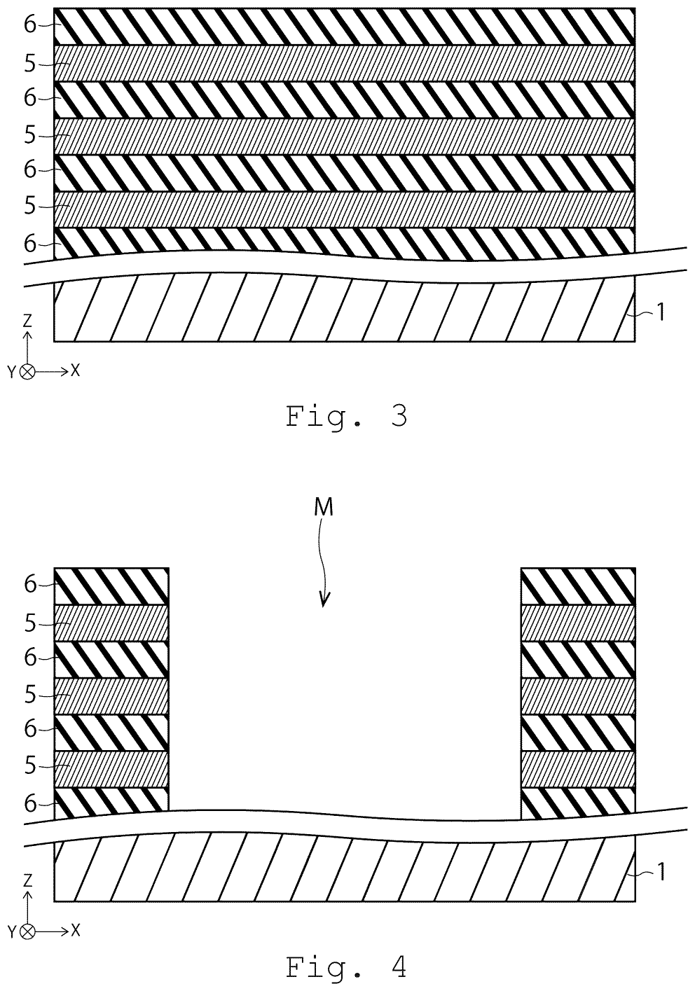

Next, the memory holes M are formed, penetrating through the electrode layers 5 and the insulating layers of the member of FIG. 3 and extending the substrate 1, to obtain the member shown in FIG. 4.

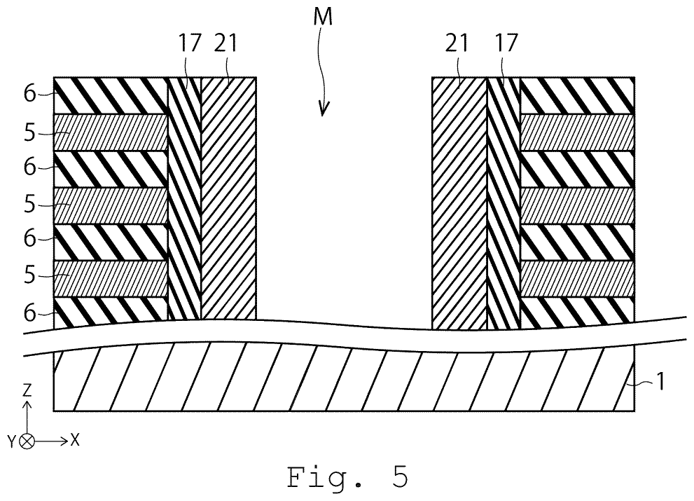

Next, the memory film (the block insulating film 12, the charge trap layer 13, and the tunnel insulating film 14) and a semiconductor layer 21 are formed in this order on the side surface of the electrode layers 5 and the insulating layers 6 in the memory holes M of the member of FIG. 4 to obtain FIG. 5.

The semiconductor layer 21 is a precursor of the channel semiconductor layer 15 of FIG. 1. The semiconductor layer 21 is an amorphous semiconductor layer, such as amorphous silicon layer. The semiconductor layer 21 is formed by LPCVD (Low Pressure Chemical Vapor Deposition) under the conditions including, for example, a temperature of 350 [° C.] or more and 550 [° C.] or less and a total pressure (or sum of the partial pressure of source gas, additive gas, and carrier gas) of 50 [Pa] or more and 500 [Pa] or less. The amorphous silicon is formed on the tunnel insulating film 14 on the memory film 17 by introducing the source gas and the additive gas.

The source gas for forming the semiconductor layer 21 is, for example, one or more organic gases selected from the group consisting of Si₂H₆ gas, SiH₄ gas, SiH₂Cl₂ gas, Si₂Cl₆, gas, and Si.

The additive gas for forming the semiconductor layer 21 is, for example, one or more selected from the group consisting of PH₃, BCl, B₂H₆, ethylene, propylene, GeH₄, N₂O, NH₃, and the like.

The carrier gas for forming the semiconductor layer 21 is, for example, one or more selected from the group consisting of N₂, H₂, Ar and the like.

Instead of alternately forming the electrode layers 5 and the insulating layers 6 on the upper insulating film 4, sacrificial layers and the insulating layers 6 may be alternately formed on the upper insulating film 4. The sacrificial layer is, for example, SiN film. In this case, the sacrificial layers are replaced with the electrode layers 5 in subsequent processes. Specifically, each of the sacrificial layers between the insulating layers 6 are selectively removed to form gaps between the insulating layers 6. The electrode layers 5 are then formed within the gaps. The method utilizing the sacrificial layers is not shown in drawings.

It is preferable to treat the surface of the semiconductor layer 21 with a dilute hydrofluoric acid solution to remove native oxide film before modifying the surface of the semiconductor layer 21 using the compound having the alkoxysilyl group or the silanol group at one end and the cation-capturing organic group at the other end (S01), or before oxidizing the surface of the semiconductor layer before modifying the surface of the semiconductor layer (S00) which is optionally performed. Although the treatment for removing the native oxide film is preferred. it may be omitted.

Prior to the modifying the compound having the alkoxysilyl group or the silanol group at one end and the cation-capturing organic group at the other end treating the surface of the semiconductor layer 21 (S00) may be optionally performed, The surface of the semiconductor layer 21 is preferably treated to increase number of OH groups on the surface of the semiconductor layer 21 with a mixture solution of ammonia water and hydrogen peroxide water, with hydrochloric acid and hydrogen peroxide water, with sulfuric acid and hydrogen peroxide water, with a mixture of CHOLINE (trimethyl(2-hydroxyethyl) ammonium hydroxide) and hydrogen peroxide water, with H₂O₂, with a mixture of hydrochloric acid, ozone water, and ultra-pure water, by thermal oxidization, or by radical oxidization. The treated member with any solution is preferably rinsed with ultra-pure water and dried at room temperature (e.g. 25 [° C.]).

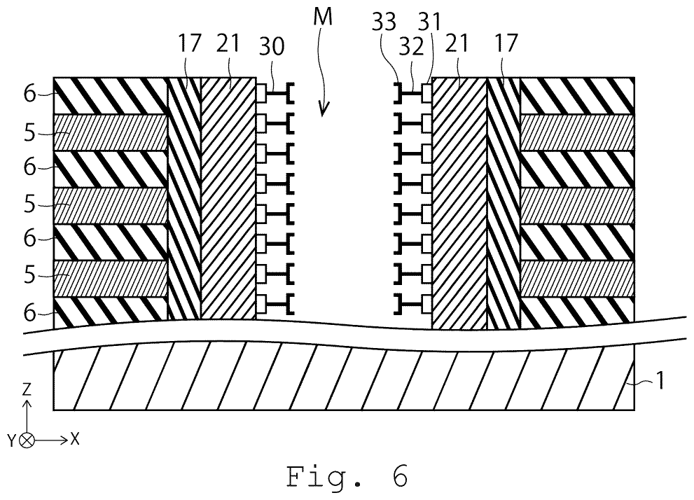

The modifying of the surface of the semiconductor layer 21 using the compound having the alkoxysilyl group or the silanol group at one end and the cation-capturing organic group at the other end (S01) will be described with reference to the schematic diagrams of FIG. 5 and FIG. 6.

Chemical modification is performed on the surface of the semiconductor layer 21 of the member shown in the schematic diagram of FIG. 1. The compound used for the chemical modification is a compound having the alkoxysilyl group at one end and the cation-capturing organic group at the other end or a compound having the silanol group at one end and the cation-capturing organic group at the other end. Silicon atom of the alkoxysilyl group or the silanol group is bonded to the semiconductor layer 21 through an oxygen atom, resulting in the member shown in the schematic diagram of FIG. 6.

The compound having the alkoxysilyl group at one end and the cation-capturing organic group at the other end is a silane-coupling agent. A silanol group which is made by hydrolysis of the alkoxysilyl group using the compound as a silane-coupling agent reacts with the OH group on the semiconductor layer 21 through a condensation reaction, and then the surface of the semiconductor layer 21 is modified with a molecule 30 including the cation-capturing organic group. The molecule 30 includes a bonding part 31 which bonds to the semiconductor layer 21, a spacer 32, and the cation-capturing organic group 33. For example, a solution containing the compound having the alkoxysilyl group at one end and the cation-capturing organic group 33 at the other end is contacted to the surface of the semiconductor layer 21. Specifically, it may be done by spraying the solution containing the compound having the alkoxysilyl group at one end and the cation-capturing organic group 33 at the other end to the semiconductor layer 21, applying the solution on the semiconductor layer 21, or dipping the semiconductor layer 21 in the solution.

The compound having the silanol group at one end and the cation-capturing organic group 33 at the other end modifies the surface of the semiconductor layer 21 by chemical deposition. When the compound having the silanol group at one end and the cation-capturing organic group 33 at the other end is used for the modification, the silanol group reacts with the OH group on the semiconductor layer 21 through a condensation reaction, and then the surface of the semiconductor layer 21 is modified with the molecule 30 including the cation-capturing organic group 33. The molecule 30 includes a bonding part 31 which bonds to the semiconductor layer 21, a spacer 32, and the cation-capturing organic group 33. Specifically, it may be done other than the chemical deposition, by spraying the solution containing the compound having the silanol group at one end and the cation-capturing organic group 33 at the other end to the semiconductor layer 21, applying the solution on the semiconductor layer 21, or dipping the semiconductor layer 21 in the solution.

The bonding part 31 which bonds to the semiconductor layer 21 is “—Si—O—”. The silicon atom of the bonding part 31 (—Si—O—) bonds to the spacer 32. The oxygen atom of the bonding part 31 (—Si—O—) bonds to the semiconductor layer 21, more specifically the oxygen atom bonds to silicon atom of the semiconductor layer 21.

The spacer 32 is preferably 1 or more and 11 or less of carbon atoms, and more preferably 1 or more and 5 or less of carbon atoms. When the number of the carbon atoms satisfies above range, the surface of the semiconductor layer 21 may be modified with the molecule 30 with high dispersibility even when modifying the memory hole M. When the modifying of the surface of the semiconductor layer 21 using the compound having the alkoxysilyl group or the silanol group at one end and the cation-capturing organic group 33 at the other end (S01) whose number of the carbon atoms satisfies above range is performed to a hole shape (the memory hole M) of the semiconductor layer 21, for example, where the semiconductor layer 21 is formed on the sidewall of the alternately stacked member with the electrode layers 5 and the insulating layers 6 the surface of the semiconductor layer 21 may be modified with the molecule 30 with high dispersibility even when an aspect ratio (depth/average hole diameter) of the memory hole M is 60 or more. The spacer 32 includes a hydrocarbon chain, which may be a linear hydrocarbon chain and/or a cyclic hydrocarbon chain. The hydrocarbon chain may be saturated or unsaturated. The cyclic hydrocarbon chain of spacer 32 preferably includes a benzene structure, piperidine structure, piperazine structure, pyrrolidine structure, triazine structure, or thiophene structure. The spacer 32 may also include one or more selected from the group consisting of an aromatic ring structure, N, S, and O. The aromatic ring structure, N, S, and O are included in a main chain and/or a side chain of the spacer 32. The N, S, and O contained in the spacer 32 may be related to bonding with metal ions.

The cation-capturing organic group 33 is not particularly limited as long as it acquires a negative charge when treated with the metal ion-containing solution (specifically, an acidic solution, more specifically, an acidic aqueous solution). The cation-capturing organic group 33 contains one or more of S, O, and N. When treated with the metal ion-containing solution, the cation-capturing organic group 33 acquires a negative charge and forms ionic bonds and/or coordination bonds with the metal ions contained in the metal ion-containing solution.

Specifically, the cation-capturing organic group 33 preferably includes one or more selected from the group consisting of —SH, —OH, —NH₂, —COOH, —NHR¹, —PH₃, —R²—NH—R³—, —R⁴—O—R⁵—, —R⁶—S—R⁷—, —COOR₈, and —CONH—. More preferably, the cation-capturing organic group 33 includes one or more selected from the group consisting of —OH, —NH₂, —COOH, —NHR¹, —R²—NH—R³—, and —R⁴—O—R⁵—. The cation-capturing organic group 33, which includes one or more of above structures, acquires a negative charge and forms ionic bonds and/or coordination bonds with the metal ions present in the metal ion-containing solution when treated with the metal ion-containing solution. The cation-capturing organic group 33 has a linear structure, a cyclic structure, or a combined structure of a linear structure and a cyclic structure. The cation-capturing organic group 33 forms ionic bonds and/or coordination bonds with one or more metal ions selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W.

When the cation-capturing organic group 33 does not include the cyclic structure, the cation-capturing organic group 33 preferably includes 2 or more and 10 or less of carbon atoms. When the cation-capturing organic group 33 includes the cyclic structure, the cation-capturing organic group 33 preferably included 10 or more and 16 or less of carbon atoms.

In view of capturing cation stably, the cation-capturing organic group 33 preferably includes two or more (more preferably three or more) of the following structures: amine, carbonyl, ester, ether, thiol, or sulfide.

R¹ is a hydrocarbon group having 1 or more and 2 or less of carbon atoms. R¹ includes carbon and hydrogen, and optionally includes one or more elements selected from the group consisting of N, S, and O. Specifically, a methyl group or an ethyl group is preferred for R¹.

R² is a hydrocarbon group having 1 or more and 2 or less of carbon atoms. R² includes carbon and hydrogen, and optionally includes one or more elements selected from the group consisting of N, S, and O. A cyclic structure formed by connecting R² and R³ may be included in the cation-capturing organic group 33. The ring members, determined independently of the above limitations of the number of carbon atoms for R² and R³, are preferably 5 or more and 20 or less. When R² and R³ are connected to form a cyclic structure, a piperidine structure, a piperazine structure, a pyrrolidine structure, or a triazine structure is preferred. When R² is a linear hydrocarbon chain, the carbon number of R² is preferably 1 or more and 2 or less.

R³ is a hydrocarbon group having 1 or more and 2 or less of carbon atoms. R³ includes carbon and hydrogen, and optionally includes one or more elements selected from the group consisting of N, S, and O. R³ may bond to one or more selected from the group consisting of —SH, —OH, —NH₂, —COOH, and —NHR¹.

R⁴ is a hydrocarbon group having 1 or more and 2 or less of carbon atoms. R⁴ includes carbon and hydrogen, and optionally includes one or more elements selected from the group consisting of N, S, and O. A cyclic structure formed by connecting R⁴ and R⁵ may be included in the cation-capturing organic group 33. The ring members, determined independently of the above limitations of the number of carbon atoms for R⁴ and R⁵, are preferably 5 or more and 20 or less. When R⁴ and R⁵ are connected to form a cyclic structure, a crown-ether structure is preferred. When R⁴ is a linear hydrocarbon chain, the carbon number of R⁴ is preferably 1 or more and 2 or less.

R⁵ is a hydrocarbon group having 1 or more and 2 or less of carbon atoms. R⁵ includes carbon and hydrogen, and optionally includes one or more elements selected from the group consisting of N, S, and O. R⁵ may bond to one or more selected from the group consisting of —SH, —OH, —NH₂, —COOH, and —NHR¹.

R⁶ is a hydrocarbon group having 1 or more and 2 or less of carbon atoms. R⁶ includes carbon and hydrogen, and optionally includes one or more elements selected from the group consisting of N, S, and O. A cyclic structure formed by connecting R⁶ and R⁷ may be included in the cation-capturing organic group 33. The ring members, determined independently of the above limitations of the number of carbon atoms for R⁶ and R⁷, are preferably 5 or more and 20 or less. When R⁶ and R⁷ are connected to form a cyclic structure, a thiophene structure is preferred. When R⁶ is a linear hydrocarbon chain, the carbon number of R⁶ is preferably 1 or more and 2 or less.

R⁷ is a hydrocarbon group having 1 or more and 2 or less of carbon atoms. R⁷ includes carbon and hydrogen, and optionally includes one or more elements selected from the group consisting of N, S, and O. R⁷ may bond to one or more selected from the group consisting of —SH, —OH, —NH₂, —COOH, and —NHR¹.

R⁸ is a hydrocarbon group having 1 or more and 2 or less of carbon atoms. R⁸ includes carbon and hydrogen, and optionally includes one or more elements selected from the group consisting of N, S, and O. R⁸ may bond to one or more selected from the group consisting of —SH, —OH, —NH₂, —COOH, and —NHR¹.

In terms of density of the chemical modification, the compound having the alkoxysilyl group or the silanol group at one end and the cation-capturing organic group 33 at the other end preferably includes an average of 1 or more and less than 2 of alkoxysilane groups or silanol groups.

Example of specific structure of the cation-capturing organic group 33 is —(C₂H₄NH)ₙ—C₂H₄NH₂ (n is 0 or more and 5 or less), —(C₃H₆NH)ₙ—C₃H₆NH₂ (n is 0 or more and 4 or less), 18-crown-6-ether (18C6), 15-crown-5-ether. (15C5), triazinethiol, —(C₂H₄NH) 3—C₂H₄NH₂, —(C₂H₄NH)₂—C₂H₄NH₂, or (C₂H₄NH)₁—C₂H₄NH₂.

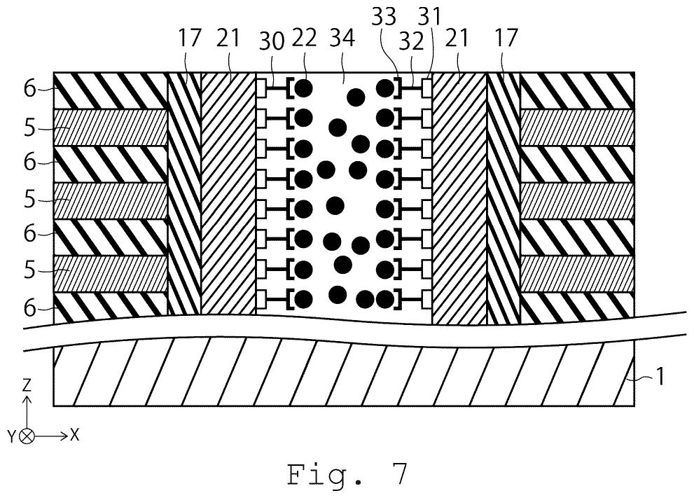

Next, the treating of the surface of the modified semiconductor layer 21 with the metal ion-containing solution 34 (S02) will be described with reference to the schematic diagram of FIG. 7. The surface of the semiconductor layer 21 of the member of FIG. 6 is treated so that the surface of the semiconductor layer 21 is contacted with the metal ion-containing solution 34. The surface of the semiconductor layer 21 is contacted with the metal ion-containing solution 34 by dipping the member of FIG. 6 in the metal ion-containing solution 34, applying the metal ion-containing solution 34 on the member of FIG. 6, or by spraying the metal ion-containing solution 34 to the member of FIG. 6.

Treating the surface of the semiconductor layer 21 with the metal ion-containing solution 34 causes negatively charged cation-capturing organic groups 33 to form ionic bonds and/or coordination bonds with metal ions 22. Multiple cation-capturing organic groups 33 may capture the single metal ion 22.

The metal ion-containing solution 34 preferably includes ions (metal ion 22) of one or more metals selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W. The metal ion-containing solution 34 more preferably includes ions (metal ions 22) of one or more metals selected from the group (first group) consisting of Au, Al, Cu, Ag, Pd, Ni, and Pt and may further includes ions (metal ions 22) of one or more metals selected from a second group consisting of Mn, Rh, Co, Fe, Cr, Ti, Nb, Ir, Ta, Re, Mo, V, Hf, Ru, Zr, and W.

Concentration of the metal ion of the metal ion-containing solution 34 is preferably 1.0×10⁻⁶ [mol/L] or more and 1.0×10⁰ [mol/L] or less.

The metal ion-containing solution 34 is preferably an acidic solution or an acidic aqueous solution. The pH of the metal ion-containing solution 34 is preferably 5 or lower. The metal ion-containing solution 34 preferably contains acid. The metal ion-containing solution 34 is preferably a nitric acid aqueous solution, hydrochloric acid aqueous solution, acetic acid aqueous solution, formic acid aqueous solution, sulfuric acid aqueous solution, oxalic acid aqueous solution, sulfamic acid aqueous solution, carbonic acid aqueous solution, or a mixture thereof.

Although the environment for the treating of the surface of the modified semiconductor layer 21 with a metal ion-containing solution 34 (S02), is not particularly limited as long as the processing temperature does not exceed the boiling point of the acid, it is preferably carried out in the atmosphere at a temperature of 0 [° C.] or more and 100 [° C.] or less, for example.

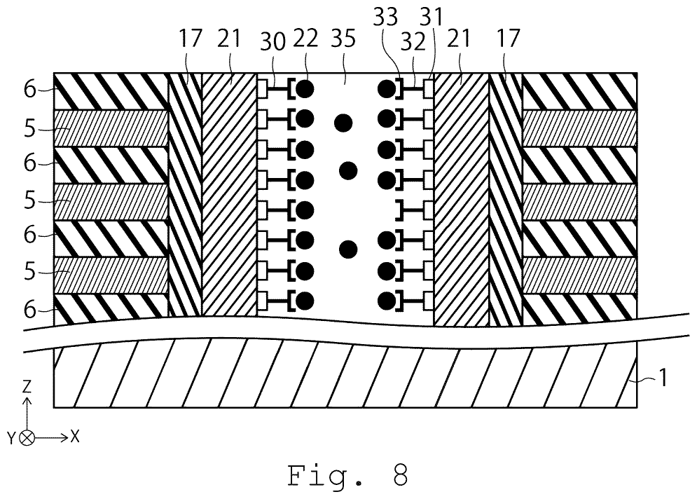

Next, the washing of the surface of the treated semiconductor layer 21 with the metal ion-containing solution 34 (S03) will be described with reference to the schematic diagram of FIG. 8. The member of FIG. 7 is washed with a cleaning liquid 35.

Washing (S03) removes some of the metal ions 22 are removed from within the memory holes M as shown in the member of the FIG. 8. Washing (S03) also removes the acid contained in the metal ion-containing solution 34. Additionally, washing (S03) may remove some of the metal ions which is bonded to the cation-capturing organic group 33. Specifically, the surface of the semiconductor layer 21 treated with the metal ion-containing solution 34 is washed multiple times with ultra-pure water as the cleaning liquid 45.

Although the environment for the washing of the surface of the treated semiconductor layer 21 with the metal ion-containing solution 34 (S03), is not particularly limited as long as the processing temperature does not exceed the boiling point of the cleaning liquid, it is preferably carried out in the atmosphere at a temperature of 0 [° C.] or more and 80 [° C.] or less, for example.

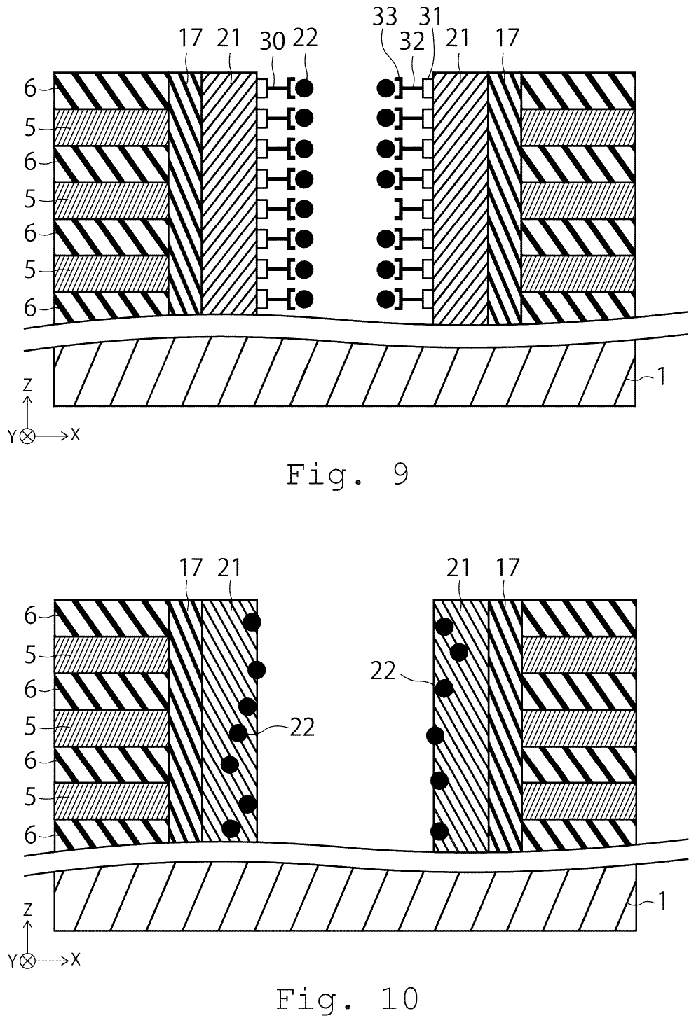

Next, the drying of the surface of the washed semiconductor layer 21 (S04) will be described with reference to the schematic diagram of FIG. 9. After washing, the surface of the semiconductor layer of the washed member of FIG. 8 is rinsed with a solvent having higher volatility than that of water, the solvent is then volatilized, or the solvent is dried by spin-dry or the similar drying process to obtain the member of FIG. 9. The solvent having higher volatility than that of water is preferably IPA (isopropyl alcohol) or others.

Next, the heating of the surface of the dried semiconductor layer 21 in the non-oxidizing atmosphere (S05) will be described with reference to the schematic diagrams of FIG. 10 through FIG. 12. The surface of the semiconductor layer 21 of the member of FIG. 9 or the overall member of FIG. 9 is heated (annealed) to decompose the molecule 30, resulting in the member shown in the schematic diagram of FIG. 10 is obtained. This process does not involve reducing metal ions 22 to form a reduced metal layer, nor does include forming a plating layer onto the reduced metal layer.

The molecule 30 is decomposed by heating the semiconductor layer 21 of the member of FIG. 9, and the metal ions 22 are migrated to the surface side of the semiconductor layer 21. Consequently, when the metal ions 22 are migrated to the surface side of the semiconductor layer 21, they can exist in various forms within the semiconductor layer 21: bound to ligands, as oxides, as hydroxides, or in other states.

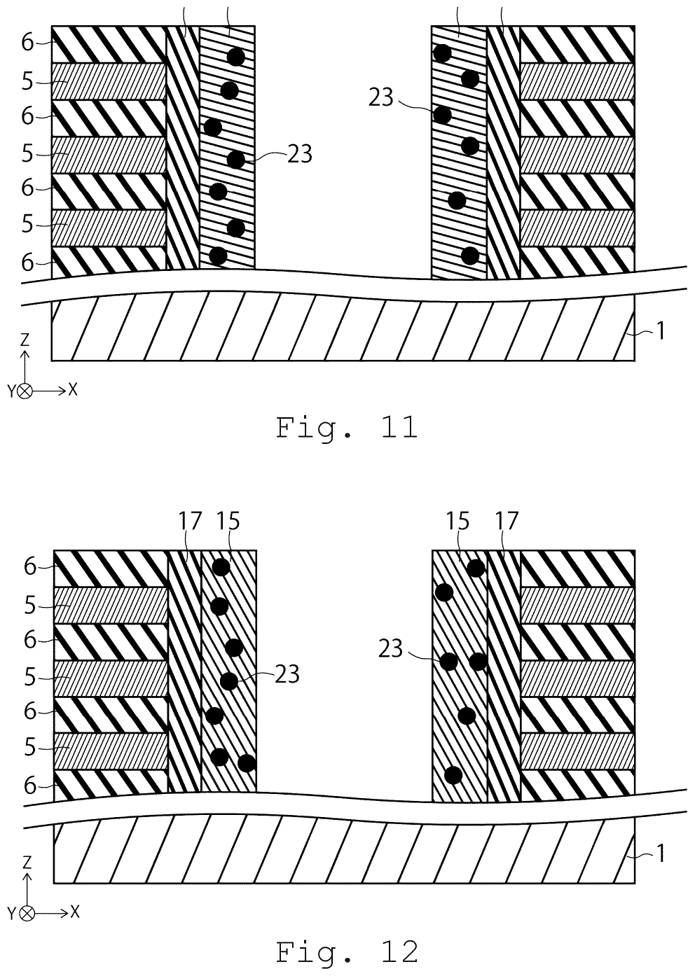

The heating of the member shown in FIG. 10 is continued, and the metal ions 22 which bond to the ligands, exist as oxides, as hydroxides, or in other states are gradually converted into silicide 23. Subsequent heating causes the silicide 23 to migrate and act as a nucleation site for crystal growth and transforming the semiconductor layer 21 into a semiconductor layer 21A, resulting in the member shown in FIG. 11.

When the heating of the member of FIG. 11 is continued, additional crystal growth in the semiconductor layer 21A is promoted. This process results in the member shown in FIG. 12, which includes the channel semiconductor layer 15 containing crystals which are grown sufficiently.

After heating in the non-oxidizing atmosphere (S05), the channel semiconductor layer 15 includes one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W. Concentration (concentration of the metal elements as atoms per surface of the channel semiconductor layer 15) of one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W in the channel semiconductor layer 15 after heating in the non-oxidizing atmosphere (S05) is preferably 7×10¹³ [atoms/cm²] or more and 1×10¹⁵ [atoms/cm²] or less.

When the processes of the embodiment is applied to the semiconductor layer 21 within the memory holes M, the channel semiconductor layer 15 also includes one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W after heating in the non-oxidizing atmosphere (S05). Concentration (concentration of the metal elements as atoms per surface of the channel semiconductor layer 15) of one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W in the channel semiconductor layer 15 after heating in the non-oxidizing atmosphere (S05) is also preferably 7×10¹³ [atoms/cm²] or more and 1×10¹⁵ [atoms/cm²] or less.

A processing atmosphere of the heating of the surface of the dried semiconductor layer 21 is preferably non-oxidative. The atmosphere preferably includes one or more selected from the group consisting of nitrogen, hydrogen, deuterium and rare gases.

A total pressure of the processing atmosphere of the heating (S05) is preferably 10 [Pa] or more and 200000 [Pa] or less, and more preferably 10 [Pa] or more and 110000 [Pa] or less.

A processing temperature for the heating (S05) is preferably 500 [° C.] or more and 1000 [° C.] or less, and more preferably 550 [° C.] or more and 950 [° C.] or less.

A processing duration of the heating (S05) is preferably 30 [min] or more and 2160 [min] or less, and more preferably 30 [min] or more and 1440 [min] or less.

The manufacturing method may further include pre-heating the surface of the semiconductor layer 21 or irradiating ultraviolet light to the surface of the semiconductor layer 21 (S06) after the washing of the surface of the treated semiconductor layer 21 and before the heating in the non-oxidizing atmosphere (S05). After performing the step (S06), the member of FIG. 10 is obtained. In this case, the member of FIG. 12 obtained from the member of FIG. 10 by heating the surface of the dried semiconductor layer 21 in the non-oxidizing atmosphere (S05).

A processing atmosphere of pre-heating the surface of the semiconductor layer 21 is preferably an oxidizing atmosphere. The atmosphere of the pre-heating (S06) preferably includes one or more selected from the group consisting of oxygen, ozone, and H₂O.

The processing temperature of the pre-heating is preferably 20 [° C.] or more and 600 [° C.] or less, and more preferably, 20 [° C.] or more and 400 [° C.] or less.

A total pressure of the processing atmosphere of the pre-heating (S06) is preferably 100 [Pa] or more and 200000 [Pa] or less, and more preferably 100 [Pa] or more and 10000 [Pa] or less.

A processing duration of the pre-heating (S06) is preferably 1 [min] or more and 60 [min] or less, and more preferably 1 [min] or more and 30 [min] or less.

A wavelength of the ultraviolet light is preferably 100 [nm] or more and 400 [nm] or less. The ultraviolet light is preferably irradiated entirely to the memory holes M.

Both a processing temperature of a processing atmosphere of the ultraviolet irradiation and a temperature of the surface of the semiconductor layer 21 while the ultraviolet light is irradiated, is preferably 20 [° C.] or more and 600 [° C.] or less and more preferably 20 [° C.] or more and 400 [° C.].

Both the ultraviolet irradiation and the pre-heating may be performed.

It is preferable that the semiconductor layer 21 is treated with a gaseous phase prior to the heating in the non-oxidizing atmosphere, following the drying of the surface of the semiconductor layer 21. When the semiconductor layer 21 is treated with liquid phase, some of the metal ions 22 may be desorbed. Therefore, treating with the gaseous phase is preferable.

Due to the pre-heating and the ultraviolet irradiation (S06) before the heating in the non-oxidizing atmosphere (S05) the semiconductor layer 21 including the metal ions 22, the semiconductor layer 21 with the metal ions 22 adhered to its surface, or the semiconductor layer 21 including the metal ions 22 and with the metal ions 22 adhered to its surface is obtained.

It is preferable to form a getter layer, such as amorphous silicon after the drying of the surface of the semiconductor layer 21 through the heating in the non-oxidizing atmosphere (S05), to migrate the silicide 23 into the getter layer, and the metal elements derived from the metal ions 22, such as silicide 23, in the channel semiconductor layer 15 is removed or reduced.

Subsequently, processes such as forming the core insulator 16 are further performed to obtain a semiconductor device 100.

The modifying of the surface of the semiconductor layer 21 using the compound having the alkoxysilyl group or the silanol group at one end and the cation-capturing organic group at the other end (S01) may enable high-density surface modification on both the bottoms and sidewalls of the memory holes M without obstructing their openings, even those with high aspect ratios. Consequently, the metal ions 22 with high concentration are captured with the cation-capturing organic group 33 on both the opening side and the bottom side of the memory holes M. Consequently, concentration gradient of the metal ions 22 which are added to the semiconductor layer 21 entirely is reduced, resulting in relatively uniform crystal growth within the channel semiconductor layer 15 even at comparatively low temperatures. During the heating in the non-oxidizing atmosphere (S05), the crystal size grows uniformly on both sides of the channel semiconductor layer 15 on a side of the substrate 1 and the channel semiconductor layer 15 on a opposite side of the substrate 1. This process reduces deviation in the mobility of the channel semiconductor layer 15 along with the Z-direction. The manufacturing method of this embodiment provides improving the channel characteristics and also advantageous for multi-level applications, even with a high number of layers.

### Second Embodiment

The second embodiment relates to a manufacturing method for a semiconductor device. The second embodiment is a variation of the first embodiment. Descriptions common to both embodiments will be omitted.

The second embodiment is applied to a semiconductor layer 41 with a planar shape not within holes rather than a semiconductor layer within a hole like the memory holes M. Except for the location, the manufacturing method of the second embodiment is similar to that of the first embodiment. In the second embodiment, the semiconductor layer 41 which is an amorphous silicon layer undergoes crystal growth to produce the semiconductor layer 42 which is a poly silicon layer as well as the first embodiment.

Hereinafter, the manufacturing method for the semiconductor device of the second embodiment will be described with reference to schematic diagrams for the manufacturing method for the semiconductor device shown in FIG. 13 through FIG. 20. A flowchart for the manufacturing method for the semiconductor device of the second embodiment is common to the flowchart shown in FIG. 2.

The modifying of the surface of the semiconductor layer 41 using the compound having the alkoxysilyl group or the silanol group at one end and the cation-capturing organic group at the other end (S01) is performed to the member shown in the schematic diagram of FIG. 13 with the semiconductor layer 41 to form the molecule 30 on the surface of the semiconductor layer 41, resulting in the member shown in the schematic diagram of FIG. 14.

Subsequently, the treating of the surface of the modified semiconductor layer 41 with the metal ion-containing solution 34 (S02) is performed to the member shown in the schematic diagram of FIG. 14. The member of FIG. 14 is treated with the metal ion-containing solution 34, and the metal ions 22 forms ionic bonds and/or coordination bonds with the cation-capturing organic group 33, resulting in the member shown in the schematic diagram of FIG. 15.

Subsequently, the washing of the surface of the treated semiconductor layer 41 with the metal ion-containing solution 34 (S03) is performed to the member shown in the schematic diagram of FIG. 15. The metal ions 22 which are not bonded to the cation-capturing organic group 33 and acid is removed by washing, resulting in the member shown in the schematic diagram of FIG. 16.

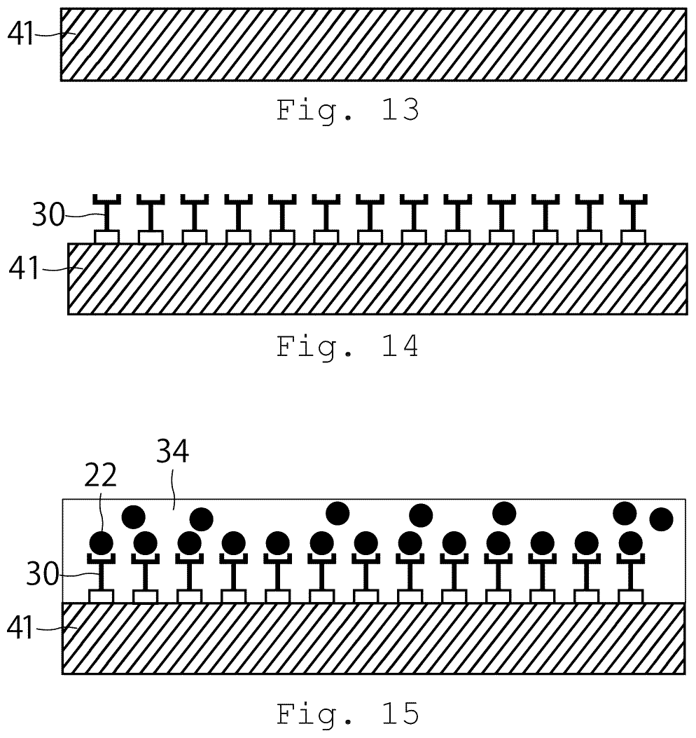

Subsequently, the drying of the surface of the washed semiconductor layer 41 (S04) is performed to the member shown in the schematic diagram of FIG. 16, resulting in the member shown in the schematic diagram of FIG. 17.

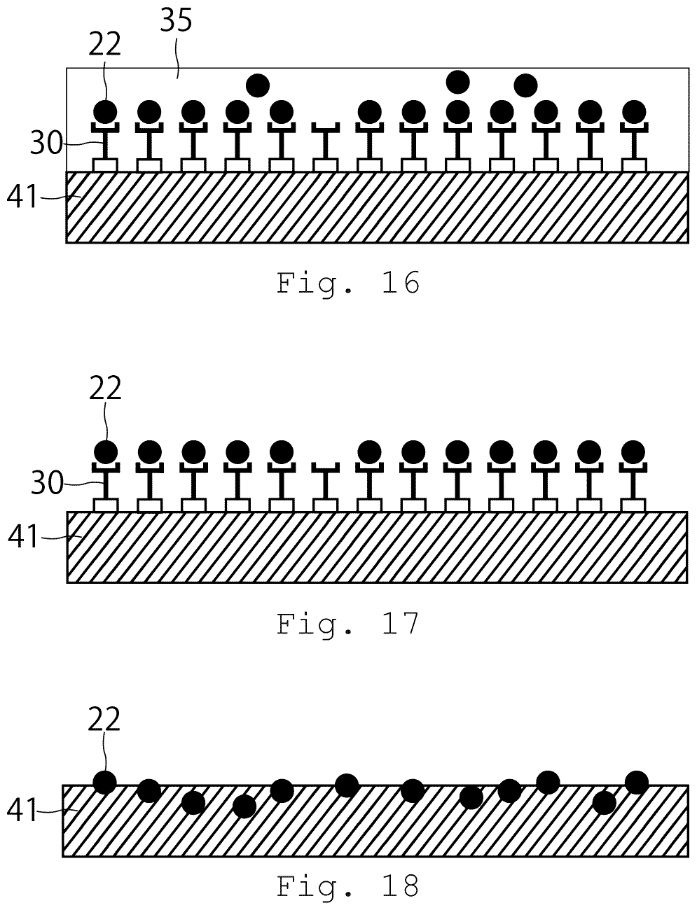

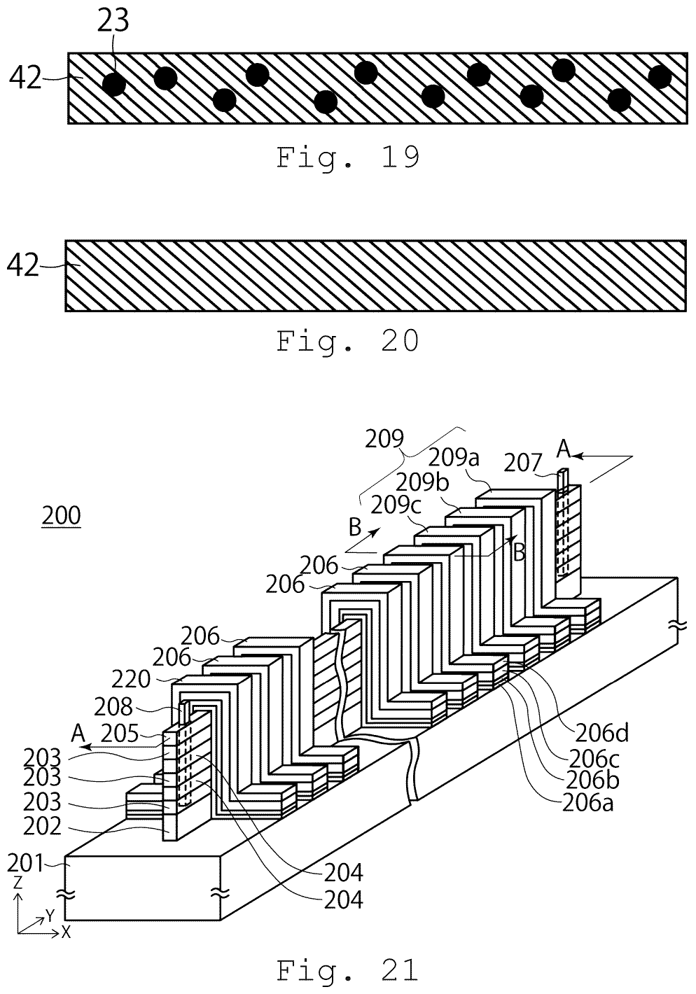

Subsequently, the heating the dried semiconductor layer surface in the non-oxidizing atmosphere (S05) is performed to the member shown in the schematic diagram of FIG. 17 to decompose the molecule 30, resulting in the member shown in schematic diagram of FIG. 18. The member of FIG. 18 is additionally heated, and the crystal growth is promoted, resulting in the member including a semiconductor layer 42 with silicide 23 shown in the schematic diagram of FIG. 19. The member of FIG. 19 may be used as a semiconductor layer for a semiconductor device.

The silicide 23 of the member shown in the schematic diagram of FIG. 19 may be removed by using the getter layer, and the member shown in the schematic diagram of FIG. 20 may be obtained. Some of the silicide 23 may remain in the semiconductor layer 42. The obtained semiconductor layer 42 of FIG. 20 may be used as a semiconductor layer for a semiconductor device.

Adopting the manufacturing method for a semiconductor device embodiment enables the transformation of the amorphous silicon to the polysilicon at relatively low temperatures. This favorable crystallization process, similar to process in the first embodiment, may be applied not only to hole-like structures such as memory holes but also to conventional layer-structured semiconductor layers like the semiconductor layer 41.

### Third Embodiment

The third embodiment relates to a manufacturing method for a semiconductor device. The third embodiment relates to a memory device with a structure distinct from the device of the first embodiment. Descriptions common to the first embodiment through the third embodiment will be omitted. Descriptions of the third embodiment may be applicable to the first embodiment and the second embodiment. A semiconductor device 200 shown in a schematic perspective diagram of FIG. 21 has a 3D semiconductor memory structure. The semiconductor device 200 shown in FIG. 21 is an example of a 3D semiconductor memory and illustrates a portion of the 3D semiconductor memory. The manufacturing method for the semiconductor device of the third embodiment is preferably applied to a stacked member of channel semiconductor layers and insulating films stacked alternately. In this embodiment, the manufacturing method for the semiconductor device 200 will be described following the description of the semiconductor device 200. Specifically, the manufacturing method for the semiconductor device of the second embodiment is adapted to the manufacturing method for the semiconductor device of the third embodiment. The semiconductor device 200 of the third embodiment has a VG (Vertical Gate) structure in which a channel semiconductor layer is parallel to a silicon substrate and a gate electrode is vertically arranged. The gate electrode sandwiches flat surfaces of the channel semiconductor layer.

The semiconductor device of FIG. 21 includes a substrate 201, an insulating film 202, a channel semiconductor layer 203, an insulating layer 204, an insulating film 205, a stacked layer 206, an electrode 207, an electrode 208, a layer-selection transistor 209 and a selection transistor 220. The memory string structures shown in FIG. 21 are preferably arranged in the X-direction.

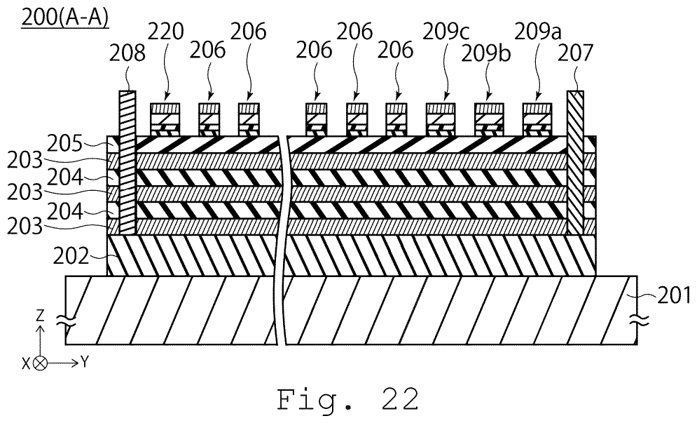

FIG. 22 illustrates a cross-sectional diagram along line A-A of the semiconductor device 200 of FIG. 21. FIG. 23 illustrates a cross-sectional diagram along line B-B of the semiconductor device 200 of FIG. 21.

The substrate (semiconductor substrate) 201 corresponds to the substrate 1 of the first embodiment. The channel semiconductor layer 203 and the insulating layer 204 are stacked alternately on the main surface of the substrate 201 via the insulating film 202. The channel semiconductor layers 203 and the insulating layers 204 are stacked following order: the channel semiconductor layer 203, the insulating layer 204. the channel semiconductor layer 203, the insulating layer 204, and the channel semiconductor layer 203. The insulating film 205 is located above the uppermost channel semiconductor layer 203.

The insulating film 202 is an insulator and located between the substrate 201 and the channel semiconductor layer 203. The insulating film 202 includes, for example, silicon oxide.

The channel semiconductor layer 203 is located between the insulating film 202 and the insulating layer 204, between the insulating layer 204 and the insulating layer 204, and between the insulating layer 204 and the insulating film 205.

Number of stacking pairs of the channel semiconductor layer 203 and the insulating layer 204 varies depending on the memory configuration. When the number of stacking pair of the channel semiconductor layer 203 and the insulating layer 204 is large, a memory capacity of the semiconductor device 200 is increased.

The channel semiconductor layer 203 is similar to the channel semiconductor layer 15 of the first embodiment and includes, for example polysilicon. The silicide 23 may be contained in the channel semiconductor layer 203.

The insulating layer 204 is an insulator and located between the channel semiconductor layers 203. The insulating layer 204 include, for example, silicon oxide.

The insulating film 205 is an insulator and located above the uppermost channel semiconductor layer 203. The insulating film 205 include, for example, silicon oxide.

The stacked component of the insulating film 202, the channel semiconductor layer 203, the insulating layer 204, and the insulating film 205 has a fin-like shape.

The stacked layer 206 is formed around the stacked component of the insulating film 202, the channel semiconductor layer 203, the insulating layer 204, and the insulating film 205. The stacked layers 206 are arranged along with the Y-direction. Each of the stacked layers 206 is separated from adjacent stacked component 205 and electrically insulated each other. In other case, the stacked layer 206 may be formed not around the stacked component of the insulating film 202, the channel semiconductor layer 203, the insulating layer 204, and the insulating film 205. The stacked layers 206 may be formed on the right side and left side of the stacked component along with the X-direction. Therefore, the insulating films 202 which is formed on the right side or left side of the stacked component along with the X-direction, may not be connected each other at the upper side of the insulating film 205.

The stacked layer 206 includes, for example, an insulating film 206a, a charge trap layer 206b, an insulating film 206c, and an electrode 206d. The insulating film 206a is located on the stacked component side, and the insulating film 206a, the charge trap layer 206b, the insulating film 206c, and the electrode 206d are stacked in this order.

The insulating film 206a is, for example, a tunnel insulating film for a memory cell. The insulating film 206a is located between the above stacked component and the charge trap layer 206b. The insulating film 206a is, for example, a silicon oxynitride film, a combination of a silicon oxide film and a silicon nitride film or the like. The insulating film 206a may further include nanoparticles of silicon or/and metal ion in the above film.

The charge trap layer 206b is located between the insulating film 206a and the insulating film 206c. The member which is used for the charge trap layer 13 is also used for the charge trap layer 206b. The charge trap layer 206b includes a silicon nitride film, a hafnium oxide film (Hf₂O), a film containing a compound including silicon atom and nitrogen atom whose composition ratio varied from silicon nitride (SiN). The charge trap layer 206b may further include nanoparticles of silicon or/and metal ion in the above film. A semiconductor layer other than the above insulating film, for example, a silicon layer may also be used for the charge trap layer 206b.

The insulating film 206c is located between the charge trap layer 206b and the electrode 206d. The insulating film 206c is, for example, a block insulating film for a memory cell. The insulating film 206c is, for example, a silicon oxide film, an aluminum oxide film (Al₂O₃), a lanthanum aluminum oxide film (LaAlO₃), a lanthanum aluminum silicon oxide film (LaAlSiO) or a film with a modified composition ratio of the constituent elements of these insulating films.

The electrode 206d is a control electrode for a memory cell. The electrode 206d is, for example, metal or/and a metal compound.

The electrode 207 is exposed on the insulating film 205 and an electrical conductor which penetrates the channel semiconductor layer 203, the insulating layer 204, and the insulating film 205. The electrode 207 is, for example, tungsten or aluminum. The electrode 207 is, for example, an independent contact for a memory cell.

The electrode 208 is exposed on the insulating film 205 and an electrical conductor which penetrates the channel semiconductor layer 203, the insulating layer 204, and the insulating film 205. The electrode 208 is, for example, tungsten or aluminum. The electrode 208 is, for example, a common contact for a memory cell.

The layer-selection transistors 209 (209a, 209b, and 209c) controls a layer (the channel semiconductor layer 203) which is selected in a memory operation. Each of the channel semiconductor layers 203 includes channel region so that the layer-selection transistor 209a connects to the channel semiconductor layer 203 located on lower side, the layer-selection transistor 209b connects to the channel semiconductor layer 203 located on the middle side, and the layer-selection transistor 209c connects to the channel semiconductor layer 203 located on the upper side.

The selection transistor 220 controls a memory string which is selected in a memory operation.

The layer-selection transistor 209 and the selection transistor 220 are drawn with a similar structure to the stacked layer 206. The layer-selection transistor 209 and the selection transistor 220 are not particularly limited as long as the channel semiconductor layer 203 functions a transistor operation as a channel.

The impurities contained in the channel region may be n-type semiconductor impurities, such as pentavalent elements, for example, arsenic (As), phosphorus (P), or combination thereof or p-type semiconductor impurities, such as trivalent elements, for example, boron (B), indium (In) or combination thereof.

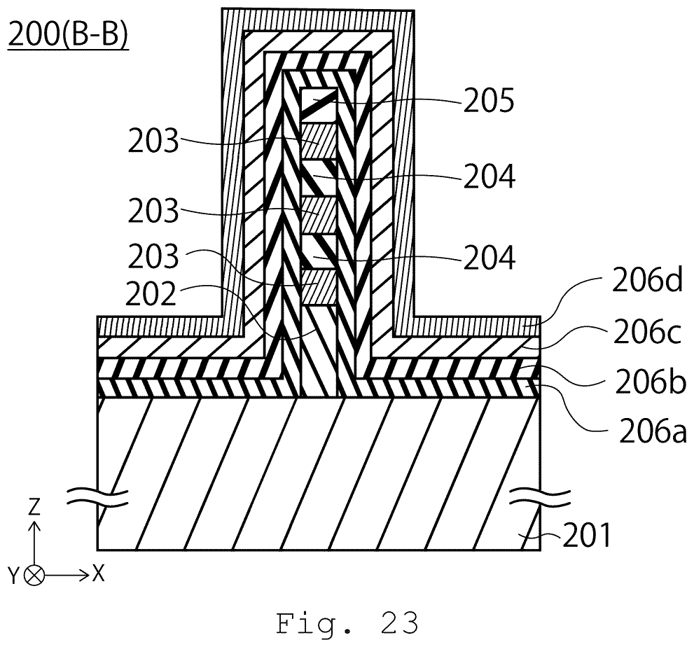

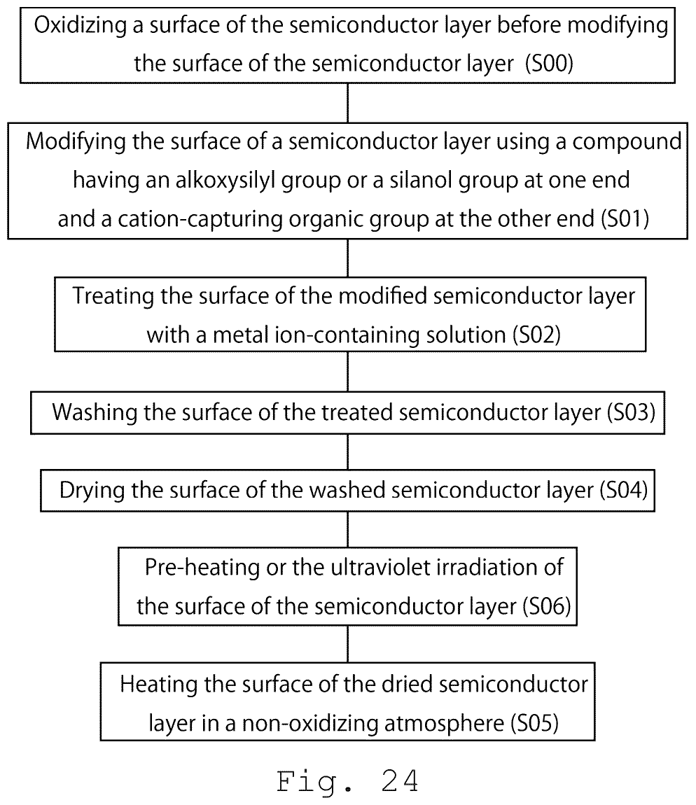

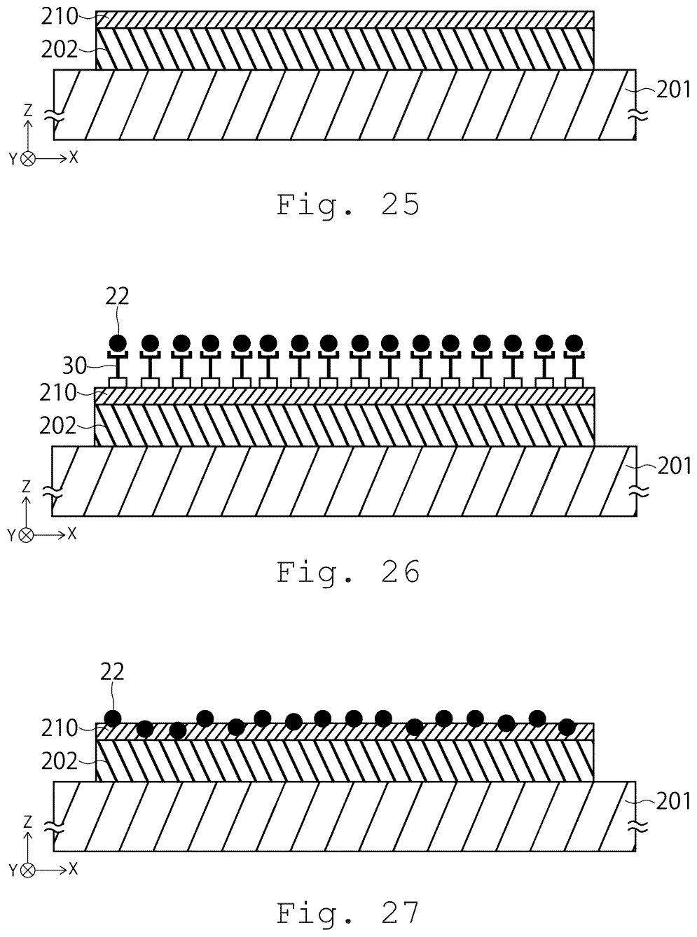

Next, the manufacturing method for the semiconductor device 200 will be described by providing several examples. The manufacturing method of the third embodiment is an example of processing to a planar semiconductor layer similar to the manufacturing method of the second embodiment. A flowchart for the manufacturing method for the semiconductor device 200 is shown in FIG. 24. Schematic diagrams for the manufacturing method for the semiconductor device 200 are shown in FIG. 25 through FIG. 35. The manufacturing method described below represents a portion of the overall manufacturing method for the semiconductor device 200.

In the description of the manufacturing method for the semiconductor device 200, the timing of steps, specifically, when the following steps: oxidizing the surface of the semiconductor layer (S00), modifying the surface of the semiconductor layer using the compound having the alkoxysilyl group or the silanol group at one end and the cation-capturing organic group at the other end (S01), treating the surface of the modified semiconductor layer with the metal ion-containing solution (S02), washing the surface of the treated semiconductor layer with the metal ion-containing solution (S03), drying the surface of the washed semiconductor layer (S04), heating the surface of the dried semiconductor layer in the non-oxidizing atmosphere (S05), and the pre-heating of the surface of the semiconductor layer or the irradiating with ultraviolet light to the surface of the semiconductor layer (S06) are performed is explained. The treatment for removing the native oxide film is preferably performed before the oxidizing of the surface of the semiconductor layer (S00).

The first example of the manufacturing method involves performing the heating of the surface of the dried semiconductor layer in the non-oxidizing atmosphere (S05) for the multiple semiconductor layers at once. The second example of the manufacturing method involves performing the heating of the surface of the dried semiconductor layer in the non-oxidizing atmosphere (S05) for each of the multiple semiconductor layers, individually. The semiconductor layer 210 corresponds to the semiconductor layer 21.

The first example of the manufacturing method involving performing the heating of the surface of the dried semiconductor layer 210 in the non-oxidizing atmosphere (S05) for the multiple semiconductor layers at once will be described. The semiconductor layer 210 which is a precursor of the channel semiconductor layer 203 is formed on the substrate 201 of the member in which the insulating film 202 is formed, resulting in the schematic diagram of FIG. 25.

Subsequently, the oxidizing of the surface of the semiconductor layer 210 (S00), the modifying of the surface of the semiconductor layer 210 using the compound having the alkoxysilyl group or the silanol group at one end and the cation-capturing organic group 33 at the other end (S01), the treating of the surface of the modified semiconductor layer 210 with the metal ion-containing solution 34 (S02), the washing of the surface of the treated semiconductor layer 210 with the metal ion-containing solution 34 (S03), and the drying of the surface of the washed semiconductor layer 210 (S04) are performed to the member shown in the schematic diagram of FIG. 25. As a result, the member shown in the schematic diagram of FIG. 26, in which the molecule 30 are bonded to the surface of the semiconductor layer 210, and the metal ions 22 are captured with the cation-capturing organic group 33 of the molecule 30, is obtained.

Subsequently, the pre-heating of the surface of the semiconductor layer 210 or the irradiating with ultraviolet light to the surface of the semiconductor layer 210 (S06) is performed on the member shown in the schematic diagram of FIG. 26. The pre-heating or the ultraviolet irradiation decomposes the molecule 30, resulting in the member of the schematic diagram in FIG. 27 having the semiconductor layer 210 including the metal ions 22, the semiconductor layer 21 with ions 22 adhered to its surface, or the semiconductor layer 21 including the metal ions 22 and with the metal ions 22 adhered to its surface.

Subsequently, the insulating layers 204 and the semiconductor layers 210 are further formed to the member of FIG. 27, the oxidizing of the surface of the semiconductor layers 210 (S00), the modifying of the surface of the semiconductor layer 210 using the compound having the alkoxysilyl group or the silanol group at one end and the cation-capturing organic group 33 at the other end (S01), the treating of the surface of the modified semiconductor layer 210 with the metal ion-containing solution 34 (S02), the washing of the surface of the treated semiconductor layer 210 with the metal ion-containing solution 34 (S03), and the drying of the surface of the washed semiconductor layer 210 (S04) is performed to the further formed semiconductor layer 210, and the pre-heating of the surface of the dried semiconductor layer 210 or the irradiating with ultraviolet light to the surface of the dried semiconductor layer 210 (S06) is performed to each of the further formed semiconductor layers 210. Repeating this set of above steps multiple times results in the member shown in the schematic diagram of FIG. 28 including desired number of layers of the semiconductor layers 210. The schematic diagram of FIG. 28 includes a number with three layers of the semiconductor layers 210.

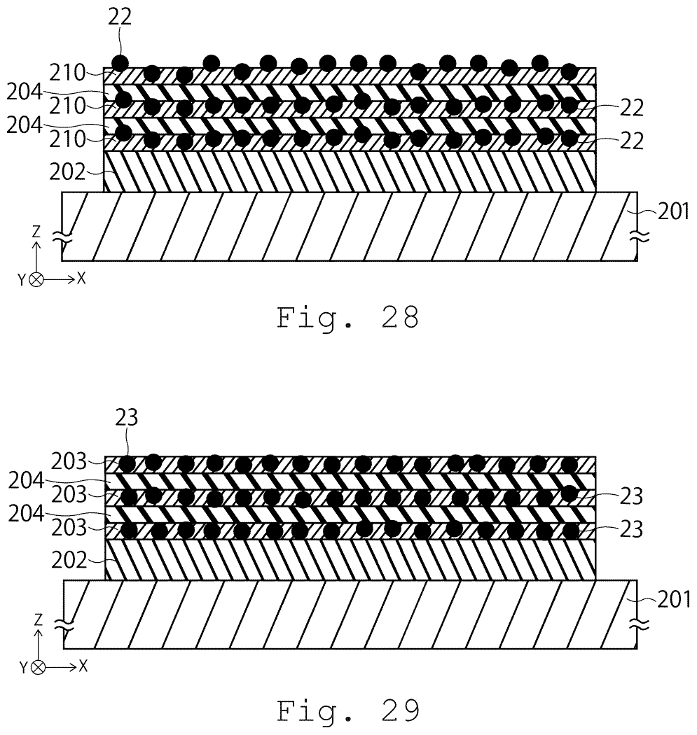

Subsequently, the heating of the surfaces of the dried semiconductor layers 210 in the non-oxidizing atmosphere (S05) is performed, promoting the crystal growth within the semiconductor layer 210. The channel semiconductor layer 203 with the silicide 23 is transformed from the semiconductor layer 210, resulting in the member of schematic diagram of FIG. 29.

For example, when forming (first forming) the semiconductor layers 210 with a stacking number of 2n (where n is a natural number), after forming the initial set of the semiconductor layer(s) 210 with a stacking number of n, the surface(s) of the dried semiconductor layers 210 may be heated (first heating) in the non-oxidizing atmosphere (S05) to grow crystals. Furthermore, after forming (second forming) an additional set of the semiconductor layer(s) 210 with a stacking number of n, the surface(s) of the dried semiconductor layer(s) 210 may be heated (second heating) in the non-oxidizing atmosphere (S05) with a total stacking number of 2n may be performed, resulting in the member shown in the schematic diagram of FIG. 29. Therefore, the processes from the step S00 to the step S05 and forming both the insulating layer 204 and the semiconductor layer 210 before step S00, may be repeatedly performed.

Subsequently, one or more getter layers 211, for example, amorphous silicon layers are formed directly on the surfaces of the channel semiconductor layers 203 of the member shown in the schematic diagram of FIG. 29, and the member is heated. The heating of the member with the getter layers 211 causes the silicide 23 to migrate into the getter layers 211, resulting in the member shown in the schematic diagram of FIG. 30.

When two cycles of the heating of the surface of the semiconductor layers 210 is performed as previously described, the forming of the getter layer 211 and the removing of the silicide 23 from the channel semiconductor layer 203 may be performed twice after each of the heating (first heating and second heating) of the surface of the dried semiconductor layer 210 in the non-oxidizing atmosphere (S05) or one time performed after the final heating (second heating) of the surface of the semiconductor layer 210 in the non-oxidizing atmosphere (S05).

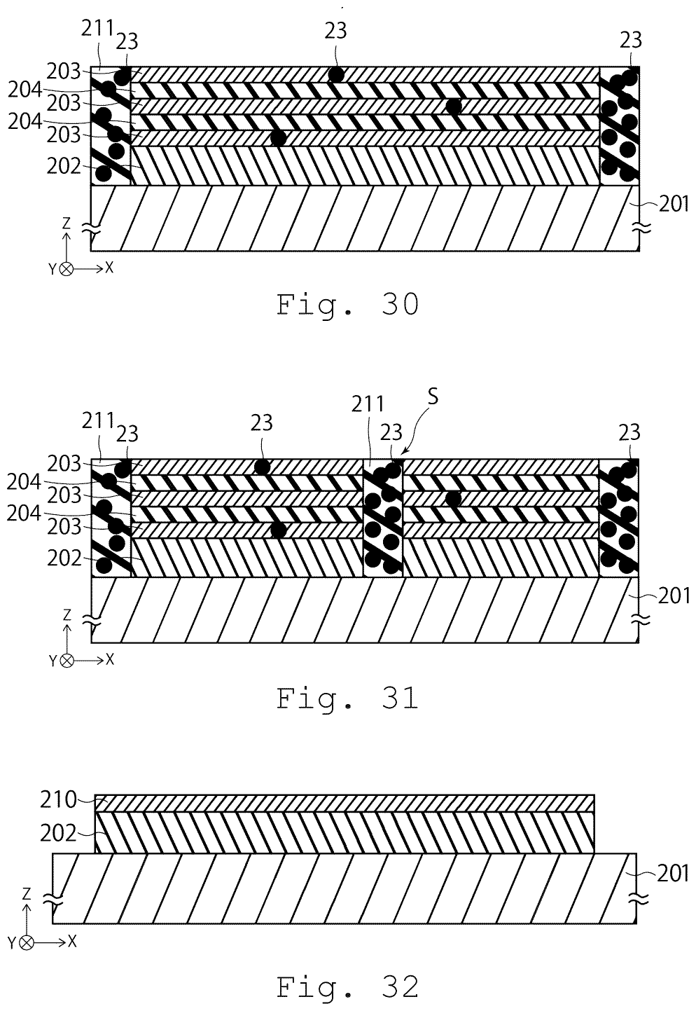

Furthermore, before the stacked component is processed into a fin-like shape in subsequent steps, one or more slits S, as shown in the schematic diagram of FIG. 31, may be formed in portions that will be removed during fin shaping. The getter layer 211 may be formed within the slit S to remove silicide 23 from the channel semiconductor layer 203.

The insulating film 205 may be formed before forming the getter layer 211 or after removing of the silicide 23 from the channel semiconductor layer 20 using the getter layer 211.

The process of the removing silicide 23 using getter layer 211 may be further performed after steps described in the specification.

After removing the getter layer 211, the layered structure comprising the desired number of the channel semiconductor layers 203 is processed into the fin-like shape. Subsequently, the electrode 207, the electrode 208, the stacked layer 206, and other components are formed to obtain the semiconductor device 200.

The second example of the manufacturing method involving performing the heating of the surface of the dried semiconductor layer in the non-oxidizing atmosphere (S05) for each of the multiple semiconductor layers, individually will be described. The semiconductor layer 210 which is a precursor of the channel semiconductor layer 203 is formed on the substrate 201 of the member in which the insulating film 202 is formed, resulting in the schematic diagram of FIG. 32.

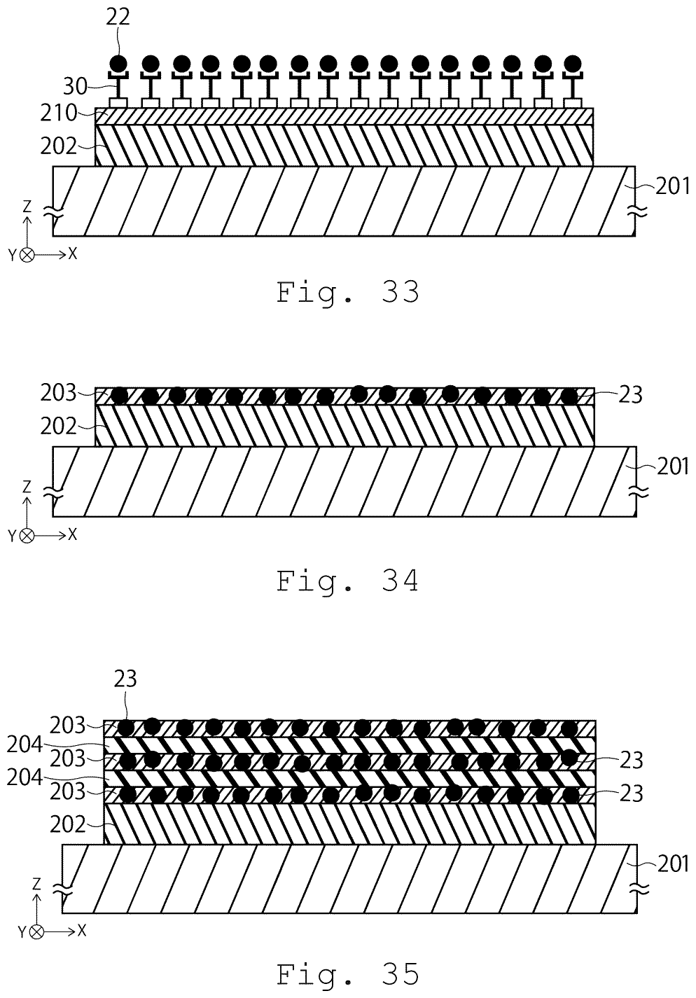

Subsequently, the oxidizing of the surface of the semiconductor layer 210 (S00), the modifying of the surface of the semiconductor layer 210 using the compound having the alkoxysilyl group or the silanol group at one end and the cation-capturing organic group 33 at the other end (S01), the treating of the surface of the modified semiconductor layer 210 with the metal ion-containing solution 34 (S02), the washing of the surface of the treated semiconductor layer 210 with the metal ion-containing solution 34 (S03), and the drying of the surface of the washed semiconductor layer 210 (S04) are performed to the member shown in the schematic diagram of FIG. 32. This process results in the member shown in FIG. 33, where the molecule 30 are bonded to the surface of the semiconductor layer 210, and the metal ions 22 are captured with the cation-capturing organic group 33 of the molecule 30.

Subsequently, the drying of the surface of the semiconductor layer 210 in the non-oxidizing atmosphere is performed to the member shown in the schematic diagram of FIG. 33. This process promotes the crystal growth within the semiconductor layer 210, resulting in the member of schematic diagram of FIG. 34, which includes the channel semiconductor layer 203 with the silicide 23 transformed from the semiconductor layer 210.

The pre-heating or the ultraviolet irradiation of the surface of the semiconductor layer 210 (S06) may be performed to the member shown in the schematic diagram of FIG. 33. When the pre-heating or the ultraviolet irradiation (S06) is performed to the surface of the semiconductor layer 210 of the member of FIG. 33 to decompose the molecule 30. As a result, the member is obtained, which includes the semiconductor layer 21 including the metal ions 22, the semiconductor layer 21 with the metal ions 22 adhered to its surface, or the semiconductor layer 21 including the metal ions 22 and with the metal ions 22 adhered to its surface. Subsequently, the heating of the surface of the dried semiconductor layer 210 in the non-oxidizing atmosphere (S05) is performed, resulting in the member shown in the schematic diagram of FIG. 34. Therefore, the second example of the manufacturing method also corresponds to the flowchart of FIG. 2.

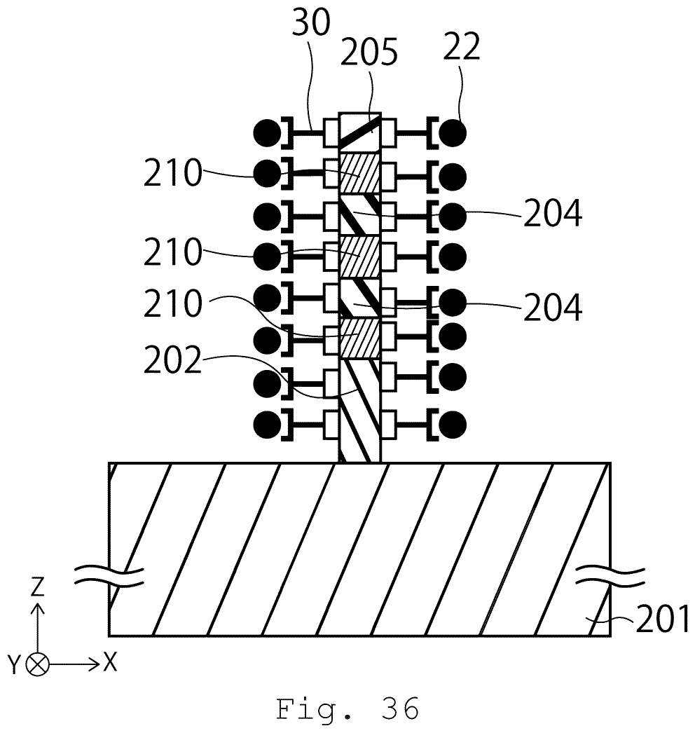

Subsequently, the insulating layer 204 and the semiconductor layer 210 are further formed to the member shown in the diagram of FIG. 34. The oxidizing of the surface of the semiconductor layer 210 (S00), the modifying of the surface of the semiconductor layer 210 using the compound having the alkoxysilyl group or the silanol group at one end and the cation-capturing organic group 33 at the other end (S01), the treating of the surface of the modified semiconductor layer 210 with the metal ion-containing solution 34 (S02), the washing of the surface of the treated semiconductor layer 210 with the metal ion-containing solution 34 (S03), the drying of the surface of the washed semiconductor layer 210 (S04), (optionally the pre-heating or the ultraviolet irradiation (S06)) and the heating of the surface of the dried semiconductor layer 210 in the non-oxidizing atmosphere (S05) is performed to the secondary formed insulating layer 204 and semiconductor layer 210, resulting in the member shown in FIG. 35, in which the secondary channel semiconductor layer 203 is formed from the secondary semiconductor layer 210.

The desired number of layers for the channel semiconductor layer 203 is achieved by repeating the aforementioned processes. Subsequently, the getter layer 211 is formed to remove the silicide 23 from the channel semiconductor layer 203. The removing the silicide 23 from the channel semiconductor layer 203 using the getter layer 211 may be performed after forming a desired number of the channel semiconductor layers 203.

After removing the getter layer 211, the stacked component with the desired number of channel semiconductor layers 203 is processed into a fin-like shape. Additionally, the electrode 207, the electrode 208, and the stacked layer 206, are formed. After performing other steps, the semiconductor device is obtained.

FIG. 36 illustrates a schematic diagram for the manufacturing method for manufacturing a semiconductor device. The schematic diagram of FIG. 36 illustrates the stacked component with fin-like shape (insulating film 202, semiconductor layer 210, insulating layer 204, semiconductor layer 210, insulating layer 204, semiconductor layer 210, insulating film 205). The schematic diagram of FIG. 36 illustrates the side surfaces of the stacked component are modified with the molecule 30 which captures he metal ions 22. The semiconductor layer 210 of such a member as illustrated in the schematic diagram of FIG. 36 may be processed into the channel semiconductor layer 203 using the aforementioned processes.

By employing the manufacturing method of the present embodiment, crystallization of the channel semiconductor layer 203 in a VG structure memory device may be achieved. The induced lateral crystallization of this embodiment may also be applied to VG structure memory devices, enabling the fabrication of memory devices with excellent channel characteristics, similar to the first embodiment.

The following examples illustrate the present embodiment specifically. These examples are applicable to any of the first, second, and third embodiments and describe phenomena common to all embodiments.

### Example 1

A sample with a hall pattern similar to a memory hole M is prepared. Amorphous silicon is deposited on the sidewalls of the hall pattern. After removing the surface native oxide film with hydrofluoric acid solution, a chemical oxide film is formed on the amorphous silicon surface using surface oxidizing agents such as SC-1, SC-2, SPM, ozone water, and hydrogen peroxide solution. Subsequently, the sample is immersed in an aqueous solution containing a silane coupling agent having —(C₂H₄NH)ₙ—C₂H₄NH₂ (where n is 0 to 5) at its end, and subsequently immerses in a metal ion-containing aqueous solution. Examples of Ni²⁺ metal ion aqueous solutions include metal ion-containing nitric acid solution, hydrochloric acid solution, acetic acid solution, formic acid solution, sulfuric acid solution, oxalic acid solution, sulfamic acid solution, or carbonic acid solution. Subsequent to each chemical treatment, the sample was washed with ultrapure water and finally dried using IPA drying or spin dry. Both single-wafer and batch processing methods can be employed for these chemical treatments and drying steps. As a result, nickel atoms are introduced into the hall pattern, and the concentration of nickel atom calculated as Blanket film is 1×10⁺¹⁴ [atoms/cm²] or more. Furthermore, annealing the hall pattern sample under the conditions of step S05 of the embodiment would result in crystallization of the amorphous silicon, with crystallization achievable in 90% or more of the area.

### Example 2

A Blanket film of amorphous silicon is prepared. The native oxide film on the surface was removed with a dilute hydrofluoric acid solution. Subsequently, a chemical oxide film is formed on the surface using oxidizing agents such as SC-1, SC-2, SPM, ozone water, and hydrogen peroxide solutions. The sample is then immersed in a diluted aqueous solution of a silane coupling agent having —(C₂H₄NH)ₙ—C₂H₄NH₂ (where n is 0 to 5) at its end, and subsequently immerses in a metal ion-containing aqueous solution. After each chemical treatment, the sample is washed with ultrapure water and finally dried using IPA drying or spin dry. Analysis of the nickel species attached to the Blanket film revealed that the species are composed of components other than NiSi₂, such as oxides or hydroxides, and metal complexes formed with ligands similar to ammonia. Annealing the Blanket film under the conditions of step (S05) of the embodiment allowed for the conversion of the attached nickel species into NiSi₂. This change in the bonding state of nickel enables the supply of NiSi₂, which acts as a crystallization nucleus, to the amorphous silicon. As a result, crystallization similar to that observed in Example 1 can be achieved.

Similar crystallization can be achieved by using other compounds as silane coupling agents. Additionally, similar crystallization can be achieved by bonding compounds with the silanol group and the cation-capturing organic group linked by a spacer to the amorphous silicon surface in the gas phase.

In the specification, some elements are represented only by chemical symbols for elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
modifying a surface of a semiconductor layer using a compound having an alkoxysilyl group or a silanol group at one end and a cation-capturing organic group at the other end;
treating the surface of the modified semiconductor layer with a metal ion-containing solution;
washing the surface of the treated semiconductor layer;
drying the surface of the washed semiconductor layer; and
heating the surface of the dried semiconductor layer in a non-oxidizing atmosphere.

2. The method according to claim 1, wherein the cation-capturing organic group comprises one or more organic groups selected from the group consisting of —SH, OH, —NH₂, —COOH, —NHR¹, —PH₃, —R²—NH—R³—, —R⁴—O—R⁵—, —R⁶—S—R⁷—, COOR⁸—, and CONH—.

3. The method according to claim 1, wherein the modifying the semiconductor layer surface using the compound having the alkoxysilyl group or the silanol group at the one end and the cation-capturing organic group at the other end is performed on a surface of the semiconductor layer which is located on a sidewall surface within a hole shape.

4. The method according to claim 1, wherein the compound comprises a spacer containing hydrocarbon between the one end and the other end.

5. The method according to claim 1, wherein the compound comprises a spacer containing hydrocarbon between the one end and the other end, and
number of carbon atoms in the spacer is 1 or more and 11 or less.

6. The method according to claim 1, wherein the compound comprises a spacer containing hydrocarbon between the one end and the other end,
number of carbon atoms in the spacer is 1 or more and 11 or less, and
the spacer includes one or more selected from the group consisting of an aromatic ring structure, N, S, and O.

7. The method according to claim 1, wherein a concentration of metal ions in the metal ion-containing solution is 1.0×10⁻⁶ [mol/L] or more and 1.0×10⁰ [mol/L] or less.

8. The method according to claim 1, wherein the metal ion-containing solution is an acidic solution whose pH is 5 or less.

9. The method according to claim 1, wherein the metal ion-containing solution includes one or more metallic ions selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W.

10. The method according to claim 1, wherein the compound contains an average of 1 or more and less than 2 of the alkoxysilyl group or the silanol group.

11. The method according to claim 1, wherein silicon atom of the alkoxysilyl group or the silanol group is bonded to the semiconductor layer through an oxygen atom in the modifying of the surface of the semiconductor layer.

12. The method according to claim 1, wherein a member where the cation-capturing organic group is bonded to a metallic ion in the metal ion-containing solution is heated in heating in the non-oxidizing atmosphere.

13. The method according to claim 1, wherein a processing temperature of the heating in the non-oxidizing atmosphere is 500 [°C] or more and 1000 [°C] or less, and
a processing atmosphere of the heating of the non-oxidizing atmosphere includes one or more selected from the group consisting of nitrogen, hydrogen, deuterium, and noble gas.

14. The method according to claim 1, wherein a processing temperature of the heating in the non-oxidizing atmosphere is 500 [° C.] or more and 1000 [° C.] or less,
a processing atmosphere of the heating of the non-oxidizing atmosphere includes one or more selected from the group consisting of nitrogen, hydrogen, deuterium, and noble gas,
a total pressure of the processing atmosphere of the heating with the non-oxidizing atmosphere is 10 [Pa] or more and 2000 [Pa] or less, and
processing duration of the heating of the non-oxidizing atmosphere is 30 [min] or more and 2160 [min] or less.

15. The method according to claim 1, the method further comprising:
pre-heating the surface of the semiconductor layer or irradiating ultraviolet light to the surface of the semiconductor layer after the washing of the surface of the treated semiconductor layer and before the heating in the non-oxidizing atmosphere.

16. The method according to claim 15, wherein
a processing atmosphere of the pre-heating is an oxidizing atmosphere,
a processing temperature of the pre-heating is 20 [° C.] or more and 600 [° C.] or less, and
processing duration of the pre-heating is 1 [min] or more and 60 [min] or less.

17. The method according to claim 15, wherein
a wavelength of the ultraviolet light is 100 [nm] or more and 400 [nm] or less,
a processing temperature of a processing atmosphere of the ultraviolet irradiation is 20 [° C.] or more and 600 [° C.] or less, and
a temperature of the surface of the semiconductor layer while the ultraviolet light is irradiated, is 20 [° C.] or more and 600 [° C.] or less.

18. The method according to claim 1, wherein the semiconductor layer after heating in the non-oxidizing atmosphere includes one or more metal elements selected from the group consisting of Au, Al, Cu, Ag, Pd, Ni, Pt, Mn, Rh, Co, Fe, Cr, Ti, Nb, Ir, Ta, Re, Mo, V, Hf, Ru, Zr, and W, and
concentration of the metal elements in the semiconductor layer after heating in the non-oxidizing atmosphere is 7×10¹³ [atoms/cm²] or more and 1×10¹⁵ [atoms/cm²] or less.

19. The method according to claim 1, the method further comprising:
oxidizing the surface of the semiconductor layer before modifying of the surface of the semiconductor layer.

20. The method according to claim 1, wherein the semiconductor layer is treated with a gaseous phase prior to the heating in the non-oxidizing atmosphere, following the drying of the surface of the semiconductor layer.
